(19) United States
(12) Patent Application Publication
(10) Pub. No.: US 2025/0055111 A1
(43) Pub. Date: Feb. 13, 2025

(54) ELECTRICAL DEVICE, ELECTRICAL SYSTEM, AND BATTERY PACK

(71) Applicant: Positec Power Tools (Suzhou) Co., Ltd, Jiangsu (CN)

(72) Inventors: Hongbing WU, Suzhou (CN); Yi ZHOU, Suzhou (CN); Jie WU, Suzhou (CN); Mengxian CHEN, Suzhou (CN)

(21) Appl. No.: 18/929,589

(22) Filed: Oct. 28, 2024

Related U.S. Application Data
(63) Continuation-in-part of application No. PCT/CN2023/090748, filed on Apr. 28, 2022.

(30) Foreign Application Priority Data
Apr. 28, 2022 (CN) 2022104574813
Mar. 24, 2023 (CN) 2023102966260

(51) Int. Cl. H01M 50/247; H01M 10/613; H01M 10/6235; H01M 10/6563; H01M 50/233; H01M 50/244; H01M 50/262

(52) U.S. Cl. CPC H01M 50/247; H01M 10/613; H01M 10/6235; H01M 10/6563; H01M 50/233; H01M 50/244; H01M 50/262; H01M 2220/30

(57) ABSTRACT

An electrical system includes a first type power tool; a second type power tool; a first battery pack comprising a first mounting portion; and a second battery pack comprising a second mounting portion. The second mounting portion is different from the first mounting portion. The first type power tool comprises a battery pack mounting portion configured to detachably engage with the first mounting portion. The second type power tool comprises a battery pack mounting part configured to detachably engage with the second mounting portion and to be non-engaged with the first mounting portion. The weight of the first battery pack is greater than or equal to 3.6 kg. The weight of the first battery pack is greater than the weight of the second battery pack. The capacity of the first battery pack is greater than the capacity of the second battery pack

### CROSS-REFERENCE TO RELATED APPLICATIONS

This application is a Continuation-in-part Application of PCT Application No. PCT/CN2023/090748, filed on Apr. 26, 2023, which claims benefit of and priority to Chinese Patent Application No. 202210457481.3, filed on Apr. 28, 2022 and Chinese Patent Application No. 202310296626.0, filed on Mar. 24, 2023, all of which are hereby incorporated by reference in their entireties for all purposes as if fully set forth herein.

### TECHNICAL FIELD

The application relates to electrical systems, and battery packs.

### BACKGROUND

A electric-powered tool is environmentally-friendly and clean, and produces relatively low noise compared with a fuel-powered tool. Therefore, the electric-powered tool is becoming increasingly popular among power tool users.

### SUMMARY

The present disclosure provides an electrical system capable of satisfying the needs of power tool users.

A technical solution adopted in the present embodiments to solve the existing technical problems is as follows:
An electrical system, wherein the electrical system comprising: A first type power tool, is configured as at least one of a backpack power tool and a wheeled power tool; A second type power tool, is configured as a handheld power tool different from the first type power tool; A first battery pack, comprising a first mounting portion; A second battery pack, comprising a second mounting portion, the second mounting portion is different from the first mounting portion; Wherein the first type power tool comprises a battery pack mounting portion configured to detachably engage with the first mounting portion; the second type power tool comprises a battery pack mounting part configured to detachably engage with the second mounting portion and to be non-engaged with the first mounting portion; Wherein the weight of the first battery pack is greater than or equal to 3.6 kg, the weight of the first battery pack is greater than the weight of the second battery pack, and the capacity of the first battery pack is greater than the capacity of the second battery pack.

In some embodiments, when the first battery pack is mounted on the battery pack mounting portion, the first battery pack supplies power to the first type power tool; and/or when the second battery pack is mounted on the battery pack mounting part, the second battery pack supplies power to the second type power tool.

In some embodiments, the battery pack mounting portion comprises a first type battery pack mechanical interface and a first type battery pack electrical interface; the battery pack mounting part comprises a second type battery pack mechanical interface and a second type battery pack electrical interface; the first mounting portion comprises a first mechanical interface and a first electrical interface; the second mounting portion comprises a second mechanical interface and a second electrical interface; the first electrical interface is electrically connected to a first type battery pack electrical interface when the first mechanical interface is engaged with the first type battery pack mechanical interface; and/or, the second electrical interface is electrically connected to a second type battery pack electrical interface when the second mechanical interface is engaged with the second type battery pack mechanical interface.

In some embodiments, the battery pack mounting portion comprises a first type battery pack mechanical interface; the battery pack mounting part comprises a second type battery pack mechanical interface; the first mounting portion comprises a first mechanical interface; the second mounting portion comprises a second mechanical interface; an engaging mode between the first type battery pack mechanical interface and the first mechanical interface is defined as a first engaging mode, and an engaging mode between the second type battery pack mechanical interface and the second mechanical interface is defined as a second engaging mode, and the first engaging mode is the same as the second engaging mode.

In some embodiments, the first mechanical interface comprises a pair of first engaging portions, the first engaging portions are configured to guide the first battery pack to engage with the battery pack mounting portion in an extending direction of the first engaging portions; and/or, the second mechanical interface comprises a pair of second engaging portions, the second engaging portions are configured to guide the second battery pack to engage with the battery pack mounting part in an extending direction of the second engaging portions.

In some embodiments, a ratio of a length of the first engaging portion to a length of the second engaging portion ranges from 1.5 to 2; and/or, a ratio of a maximum distance between the pair of first engaging portions to a maximum distance between the pair of second engaging portions ranges from 1.5 to 2.5.

In some embodiments, a ratio of energy of the first battery pack to an area of an engaging region defined by the pair of first engaging portions is defined as a first battery pack energy loading ratio, a ratio of energy of the second battery pack to an area of an engaging region defined by the pair of second engaging portions is defined as a second battery pack energy loading ratio, the first battery pack energy loading ratio is in a range of 2.05 to 5.58 Wh/cm², and/or the second battery pack energy loading ratio is in a range of 1.20 to 7.20 Wh/cm².

In some embodiments, the pair of first engaging portions are arranged face to face, and the pair of second engaging portions are arranged back to back.

In some embodiments, the first electrical interface is the same as the second electrical interface.

In some embodiments, the ratio of the weight of the first battery pack to the weight of the second type power tool is 0.5-4.

In some embodiments, the electrical system further comprises a backpack device configured to be carried on back by a user, the backpack device comprises a cable, a plug and a backpack mounting portion, the cable is configured to connect the plug and the backpack mounting portion, the backpack mounting portion is configured to detachably mount the first battery pack, the plug is configured to detachably engage the second type power tool, the first battery pack powering the second type power tool when the second type power tool is engaged to the plug and the first battery pack is mounted to the backpack mounting portion.

In some embodiments, the battery pack mounting portion is configured to detachably engage with the second mounting portion to cause the second battery pack to power the first type power tool.

In some embodiments, when the battery pack mounting portion is engaged with one of the first mounting portion or the second mounting portion, the other of the first mounting portion or the second mounting portion cannot be engaged with the battery pack mounting portion.

In some embodiments, the battery pack mounting portion comprises a pair of first guiding portions and a pair of second guiding portions, the first guiding portions are configured to guide the first battery pack to engage with the first type power tool in an extending direction of the first guiding portions, the second guiding portions are configured to guide the second battery pack to engage with the first type power tool in an extending direction of the second guiding portions.

In some embodiments, the first guiding portions and the second guiding portions are independent of each other.

In some embodiments, in a width direction, the pair of first guiding portions are located on two sides of the pair of second guiding portions.

In some embodiments, the battery pack mounting portion further comprises a first support portion and a second support portion that extend in an extending direction of the first guiding portions, the pair of first guiding portions comprise a pair of first extension portions that extend in an extending direction of the first guiding portions, the pair of second guiding portions comprise a pair of second extension portions that extend in an extending direction of the second guiding portions, the pair of first extension portions respectively protrude from outer sides of the first support portion and the second support portion in the width direction, and the pair of second extension portions respectively protrude from inner sides of the first support portion and the second support portion in the width direction.

In some embodiments, a ratio of a length of the first guiding portion to a length of the second guiding portion ranges from 1.5 to 2; and/or, a ratio of a maximum distance between the pair of first guiding portions to a maximum distance between the pair of second guiding portions ranges from 1.5 to 2.5.

In some embodiments, the pair of first guiding portions are arranged back to back, and the pair of second guiding portions are arranged face to face.

In some embodiments, the first type battery pack electrical interface further comprises a plurality of device terminals, the device terminals are configured as, when the first battery pack engages with the first type power tool, the device terminals are electrically connected to corresponding terminals of the first battery pack; and when the second battery pack engages with the first type power tool, the device terminals are electrically connected to corresponding terminals of the second battery pack.

In some embodiments, a ratio of the weight of the first battery pack to the weight of the second battery pack ranges from 2 to 8.

In some embodiments, the weight of the first battery pack ranges from 4 to 12 Kg, and/or, the weight of the second battery pack ranges from 1.2 to 3.5 Kg.

In some embodiments, a ratio of the energy of the first battery pack to the energy of the second battery pack is greater than or equal to 2.

In some embodiments, the energy of the first battery pack ranges from 600 to 1800 Wh, and/or, the energy of the second battery pack ranges from 120 to 720 Wh.

In some embodiments, the first battery pack comprises a first housing and at least one first battery cell accommodated in the first housing, the charging rate of each first battery cell is configured such that the ratio of the charging time to the discharging time of the first battery cell is 0.7-1.5; and/or, the second battery pack comprises a second housing and at least one second battery cell accommodated in the second housing, the charging rate of each second battery cell is configured such that the ratio of the charging time to the discharging time of the second battery cell is 0.7-1.5.

In some embodiments, the continuous charging rate of each first battery cell is greater than 3C; and/or, the continuous charging rate of each second battery cell is greater than 3C.

In some embodiments, the ratio of the rated energy to the weight of the first battery pack is in a range of 60-300 Wh/Kg; and/or, the ratio of the rated energy to the weight of the second battery pack is in a range of 60-300 Wh/Kg.

In some embodiments, the electrical system further includes a charger, the charger comprises a battery pack mounting portion configured to detachably engage with the first mounting portion or the second mounting portion to charge the first battery pack or the second battery pack.

The present embodiments provides a first battery pack, comprising, a first housing; at least one first battery cell accommodated in the first housing; a first mounting portion, is configured to detachably engage with an electrical device, the first mounting portion comprises a first mechanical interface and a first electrical interface; the weight of the first battery pack is greater than or equal to 3.6 kg; the first electrical interface is electrically connected to corresponding electrical interface of the electrical device when the first mechanical interface is engaged with corresponding mechanical interface of the electrical device.

In some embodiments, the first electrical interface comprises a plurality of first terminals, when the first mounting portion engages with the electrical device, the first terminals are electrically connected to corresponding terminals of the electrical device.

In some embodiments, the first mechanical interface comprises a pair of first engaging portions, the first engaging portions are arranged on the first housing, the first engaging portions are configured to guide the first battery pack to engage with the electrical device in an engaging direction, the engaging direction is configured as an extending direction of the first engaging portions.

In some embodiments, in the engaging direction, a ratio of a length of the first engaging portion to a length of the first housing ranges from 0.23 to 0.89; and/or, in the width direction perpendicular to the engaging direction, a ratio of a maximum distance between the pair of first engaging portions to the width of the first housing ranges from 0.56 to 0.69.

In some embodiments, in the width direction perpendicular to the engaging direction, the first terminals located between the pair of first engaging portions.

In some embodiments, the pair of first engaging portions are configured as a pair of inner slide rails.

In some embodiments, the first mechanical interface further comprises a first locking portion, and when the first battery pack engages with the electrical device, the first locking portion is configured to engage with a locking member of the electrical device, to lock the first battery pack to the electrical device.

In some embodiments, the first mechanical interface comprises a pair of first engaging portions, the first engaging portions are arranged on the first housing, the first engaging portions are configured to guide the first battery pack to engage with the electrical device in an engaging direction; in the width direction perpendicular to the engaging direction, a first locking portion is located between the pair of first engaging portions, the engaging direction is configured as an extending direction of the first engaging portions.

In some embodiments, the energy of the first battery pack ranges from 600 to 1800 Wh, and/or, the weight of the first battery pack ranges from 4 to 12 Kg.

In some embodiments, a ratio of energy of the first battery pack to an area of an engaging region defined by the pair of first engaging portions is defined as a first battery pack energy loading ratio, the first battery pack energy loading ratio is in a range of 2.05 to 5.58 Wh/cm².

In some embodiments, the first battery pack further comprises a handle located at one end of the first housing, and the handle is enclosed with the first housing to form a grip area.

The present embodiments provides a first battery pack, comprising, a first housing; at least one first battery cell accommodated in the first housing; the weight of the first battery pack is greater than or equal to 3.6 kg; the first battery pack further comprises a first air vent disposed on the first housing, the first air vent configured to be at least partially aligned with an device air vent of the electrical device when the first battery pack is engaged with the electrical device to allow airflow to flow between the first air vent and the device air vent.

In some embodiments, the first battery pack comprises a pair of first engaging portions, the first engaging portions are configured to guide the first battery pack to engage with the electrical device in an engaging direction, in the width direction perpendicular to the engaging direction, the first air vent is located between the pair of first engaging portions, the engaging direction is configured as an extending direction of the first engaging portions.

The present embodiments provides an electrical system comprising a first battery pack and an electrical device, the first battery pack is detachably engaged with an electrical device, the first battery pack comprises: a first housing; at least one first battery cell accommodated in the first housing; a first air vent, disposed on the first housing; the weight of the first battery pack is greater than or equal to 3.6 kg; the electrical device comprises: a device housing; a fan, disposed within the device housing; a device air vent, located on the device housing, the first air vent configured to be at least partially aligned with an device air vent when the first battery pack is engaged with the electrical device, the fan is configured as, drive airflow flows between the first air vent and the device air vent.

In some embodiments, the first battery pack comprises a pair of first engaging portions, the first engaging portions are configured to guide the first battery pack to engage with the electrical device in an engaging direction; the electrical device comprises a pair of first guiding portions, the first guiding portions are configured to engaged with the first engaging portions; in the width direction perpendicular to the engaging direction, the first air vent located between the pair of first engaging portions, the device air vent located between the pair of first guiding portions, the engaging direction is configured as an extending direction of the first engaging portions.

In some embodiments, the first battery pack further comprises an air inlet, when the first battery pack is engaged with the electrical device, the fan is configured as, drive airflow flows into the first housing from the air inlet, flows out from the first air vent after cooling the first battery cell.

In some embodiments, the air inlet is located at least partially at a side or bottom of the first housing.

In some embodiments, a electrical system further comprises a second battery pack, the second battery pack is detachably engaged with an electrical device, the second battery pack comprises: a second housing; at least one second battery cell accommodated in the second housing; a second air vent, located on the second housing; the weight of the second battery pack is less than 3.6 kg; the second air vent configured to be at least partially aligned with an device air vent when the second battery pack is engaged with the electrical device, the fan is configured as, drive airflow flows between the second air vent and the device air vent.

### BRIEF DESCRIPTION OF THE DRAWINGS

The foregoing objects, technical solutions, and beneficial effects of the present embodiments can be implemented with reference to the accompanying drawings below:

FIG. 1 is a schematic diagram of an electrical system provided by the present embodiments.

FIG. 2 is a schematic diagram of a first battery pack in the electrical system shown in FIG. 1 that can be mounted to a first type power tool.

FIG. 3 is a schematic diagram of a first battery pack in the electrical system shown in FIG. 1 being mounted to a lawn mower.

FIG. 4 is a schematic diagram of a battery pack mounting portion of a first type power tool in the electrical system shown in FIG. 1.

FIG. 5 is a schematic diagram of a first battery pack in the electrical system shown in FIG. 1.

FIG. 6 is a schematic diagram of a second battery pack in the electrical system shown in FIG. 1 that can be mounted to a second type power tool.

FIG. 7 is a schematic diagram of a second battery pack in the electrical system shown in FIG. 1 being mounted to a lawn mower.

FIG. 8 is a schematic diagram of a second battery pack in the electrical system shown in FIG. 1.

FIG. 9 is a schematic diagram of a second battery pack in the electrical system shown in FIG. 1 that can be mounted to a first type power tool.

FIG. 10 is a schematic diagram of a second battery pack in the electrical system shown in FIG. 1 being mounted to a lawn mower.

FIG. 11 is a schematic diagram of a first battery pack mounted to a backpack blower in the electrical system shown in FIG. 1.

FIG. 12 is a schematic diagram of a first battery pack in the electrical system shown in FIG. 1 supplying power to a second type power tool through a backpack device.

FIG. 13 is a schematic diagram of a backpack device in the electrical system shown in FIG. 1.

FIG. 14 is a schematic diagram of a second battery pack in the electrical system shown in FIG. 1 supplying power to a second type power tool through a backpack device.

FIG. 15 is a schematic diagram in which an electrical device according to the present embodiments is configured as a charger.

FIG. 16 is a front view of the electrical device shown in FIG. 15.

FIG. 17 is a schematic diagram of the electrical device shown in FIG. 15 engaging with a first battery pack.

FIG. 18 is a schematic diagram of the electrical device shown in FIG. 15 engaging with a second battery pack.

FIG. 19 is a schematic diagram of a device air vent of the electrical device shown in FIG. 15 aligned with a first air vent of a first battery pack.

FIG. 20 is a schematic diagram of a device air vent of the electrical device shown in FIG. 15 aligned with a second air vent of a second battery pack.

FIG. 21 is a schematic diagram in which an electrical device according to the present embodiments is configured as a back rack.

FIG. 22 is a schematic top view of a cross-sectional structure in which a first battery pack engages with the electrical device shown in FIG. 21 in a direction A-A in FIG. 21.

FIG. 23 is a schematic top view of a cross-sectional structure in which a second battery pack engages with the electrical device shown in FIG. 21 in a direction A-A in FIG. 21.

FIG. 24 is a schematic diagram in which an electrical device according to the present embodiments is configured as a lawn mower.

FIG. 25 is a schematic diagram of a battery pack according to the present embodiments.

### DETAILED DESCRIPTION

This application is described in detail below with reference with the embodiments shown in the accompanying drawings. However, these embodiments do not limit this application, and structural, methodological, or functional transformations made by a person of ordinary skill in the art according to these embodiments are included in the protection scope of this application.

It should be noted that when a component is referred to as “being fixed to” another component, the component may be directly on the other component, or an intervening component may be present. When a component is considered to be “connected to” another component, the component may be directly connected to the another component, or an intervening component may also be present. In the shown embodiments, direction representations, that is, upper, lower, left, right, front, and rear, are relative, and are used to explain that structures and movements of different components in this application are relative. These representations are appropriate when the components are at the positions shown in the drawings. However, if descriptions of component positions are changed, it is considered that the representations are also changed correspondingly.

Unless otherwise defined, meanings of all technical and scientific terms used in this specification are the same as those usually understood by a person skilled in the art to which this application belongs. In this application, terms used in the specification of this application are merely intended to describe objectives of the specific embodiments, but are not intended to limit this application. The term “and/or” used in this specification includes any and all combinations of one or more related listed items.

Electricity is an environmentally friendly and clean energy. Therefore, power tools are becoming more and more popular among people. In particular, the garden maintenance work itself has the attribute of green and environmental protection, so for gardeners, power tools are the most ideal choice.

For commercial garden tools, a common usage scenario is that 2-3 workers form a team and work outside for a day to decorate gardens for 10-20 families. Once one garden is finished, the team will go to another garden and repeat the above work process until all the work tasks for today are completed. It can be seen from this that the workload of garden maintenance work is very large and the demand for energy is very high.

The shapes of different garden tools are quite different, which can be divided into the following two types: the first type is backpack power tools and wheeled power tools, wheeled power tools include lawn mowers, etc., and backpack power tools include backpack blowers, etc.; The second type is handheld power tools, such as handheld blowers, lawn mowers, hedge trimmers, etc. The first type power tools and the second type power tools also have different needs for battery packs.

The inventors of the present application have keenly recognized that gardeners usually need to purchase two different types of battery packs to meet the two types of power tools with different usage scenarios, and this is analyzed in detail below.

When the first battery pack supplies power to the backpack power tool, the user carries the battery pack on his back to reduce the load pressure. When the first battery pack supplies power to the wheeled power tool, since the wheeled power tool includes wheels, the user directly mounts the battery pack on the wheeled power tool, and the wheeled power tool is moved by the wheels, and the user does not need to carry weight. Therefore, the first type power tool does not require high load of the user when used. Therefore, the weight of the first battery pack that supplies power to the first type power tool may be larger, so that the first battery pack can also provide a larger capacity, so that the first battery pack can provide a long endurance for the first type power tool, and avoid a reduction in working efficiency due to a small battery pack capacity that requires frequent replacement of the battery pack.

When user use the second type power tool, he needs to use his hand to support it, while user of commercial garden tools usually needs to work for a long time, and the user's hands cannot continue to bear a large weight. Therefore, the weight of the second battery pack mounted on the second type power tool cannot be too large. Correspondingly, the capacity of the second battery pack is also smaller, making it more convenient for users to use the battery pack hand-held and the cost is lower. Therefore, in order to match the usage needs of different power tools, user need to purchase two different types of battery packs, namely, a first battery pack and a second battery pack.

Through research, the inventors of the present application have found that when the weight of the battery pack is greater than or equal to 3.6 Kg, it is difficult for users to hold it by hand when using it for a long time. Therefore, for the sake of humanization, users of commercial garden tools cannot hold a battery pack with a weight of greater than or equal to 3.6 Kg for a long time. In other words, a battery pack with a weight of greater than or equal to 3.6 Kg does not need to be mounted on the second type power tool.

Further, the weight of the first battery pack is greater than the weight of the second battery pack, which also puts higher requirements on the strength of the mounting portion of the first type power tool to which the first battery pack is mounted, and the mounting portion of the first type power tool needs to be different from the mounting portion of the second type power tool, so as to prevent the strength of the mounting portion of the second type power tool from being insufficient to support the first battery pack.

Therefore, the embodiment of the present application provides an electrical system, which uses the first battery pack to be mounted on the first type power tool, uses the second battery pack to be mounted on the second type power tool, and the first battery pack cannot be mounted on the second type power tool, so that the user does not need to frequently replace the battery pack, the work efficiency is improved, and the first battery pack is reliably supported on the first type power tool to avoid engaging failure, and at the same time, the weight of the user is not too large and the operation is comfortable. The electrical system will be described in detail below.

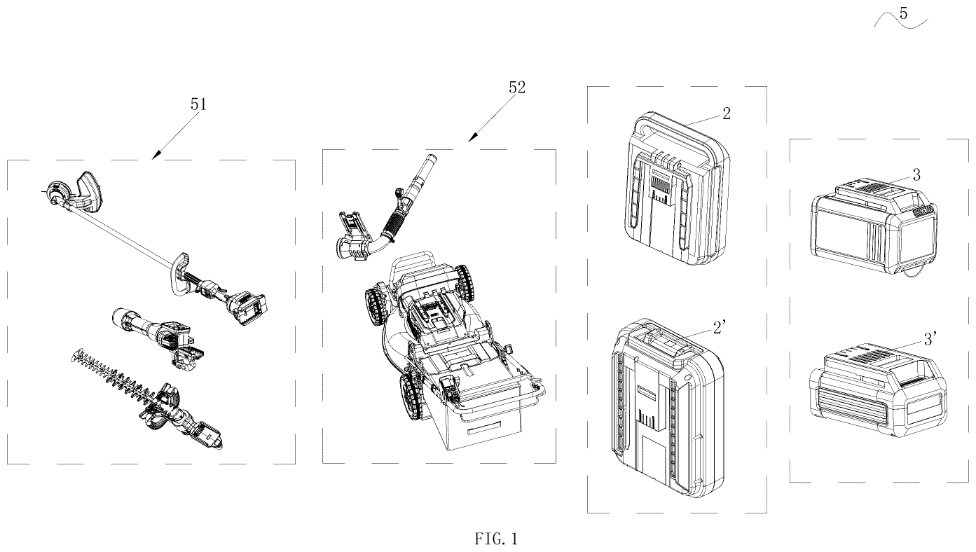

Referring to FIG. 1, some embodiments of the present application provide an electrical system 5, and the electrical system 5 includes a first type power tool 51 and a second type power tool 52. The first type power tool 51 is configured as at least one of a backpack power tool and a wheeled power tool. The second type power tool 52 is configured as a handheld power tool different from the first type power tool.

The electrical system 5 may include one or more first type power tools 51. The tool types of the plurality of first type power tools may be different or the same, or some of the first type power tools may be the same and some of the first type power tools may be different. The electrical system 5 may also include one or more second type power tools 52. The tool types of the plurality of second type power tools may be different or the same, or some of the second type power tools have the same types and some of the second type power tools have different types.

The number of the first type power tools 51 and the second type power tools 52 may be the same or different. For example, if the work content to be performed by the power tool system is relatively simple, which can be completed by one first type power tool and one second type power tool, only one first type power tool and one second type power tool can be configured for the user. For another example, if the work content to be performed by the power tool system is diverse, and a plurality of first type power tools and a plurality of second type power tools are required to cooperate with each other to complete it, in this case, a plurality of first type power tools and a plurality of second type power tools may be configured for a user of the electrical system.

The electrical system 5 further includes a first battery pack and a second battery pack. The first battery pack may be one or more. The plurality of first battery packs may all be of the same type, all of them may be of different types, or some of the first battery packs may be of the same type and some of the first battery packs may be of different types. The second battery pack may be one or more. The plurality of second battery packs may all be of the same type, all of them may be of different types, or some of the second battery packs may be of the same type and some of the second battery packs may be of different types.

It should be noted that, “different types of battery packs” as used herein refers to one or more types of differences in the capacity of the battery cells, the type of the battery cells, the internal structure of the battery packs, the outer shape of the battery packs, and the like.

In some embodiments, as shown in FIG. 1, the first battery pack includes first battery pack 2 and first battery pack 2′, and the second battery pack includes second battery pack 3 and second battery pack 3′, wherein the capacities, types of battery cells, and internal structures and shapes of the two first battery packs 2 and 2′ are different, and the capacities, types of battery cells, and internal structures and shapes of the two second battery packs 3 and 3′ are also different.

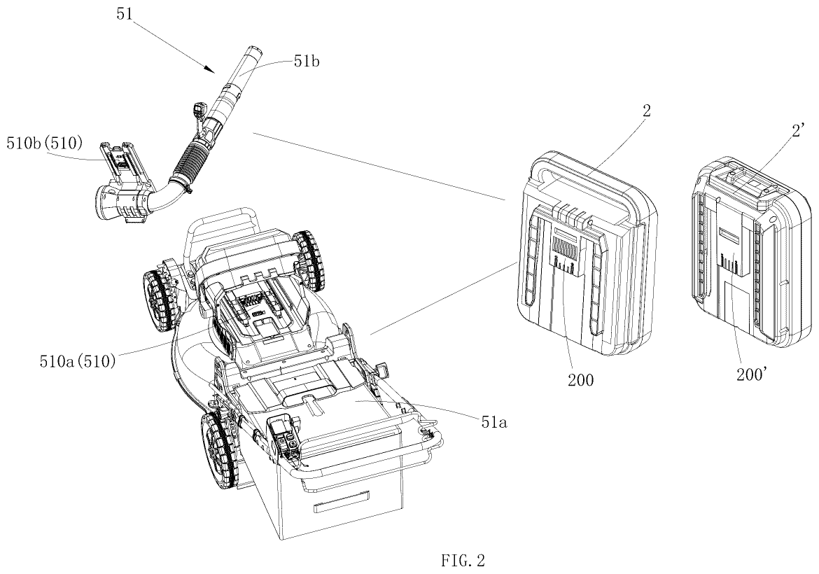

As shown in FIG. 2, the first type power tool 51 includes a battery pack mounting portion 510 configured to detachably mount the first battery packs 3, 3′. When the first battery packs 3, 3′ are mounted on the battery pack mounting portion 510, the battery pack mounting portion 510 provides reliable support for the first battery packs 3, 3′. In other words, a plurality of different types of the first type power tools each have a battery pack mounting portion having the same structure for mounting the first battery pack.

Correspondingly, the first battery packs 2, 2′ include first mounting portions 200, 200′ respectively, and the first mounting portions 200, 200′ are configured to be detachably engaged with the battery pack mounting portion 510. In other words, a plurality of different types of first battery packs each have a first mounting portion having the same structure for mounting to the first type power tool.

As shown in FIG. 2, the first type power tool 51 includes a lawn mower 51a and a backpack blower 51b. The lawn mower 51a includes a battery pack mounting portion 510a, and the backpack blower 51b includes a battery pack mounting portion 510b, and the battery pack mounting portions 510a and 510b have the same structure, and each of the first battery packs 2 and 2′ is detachably mountable to the battery pack mounting portions 510a and 510b.

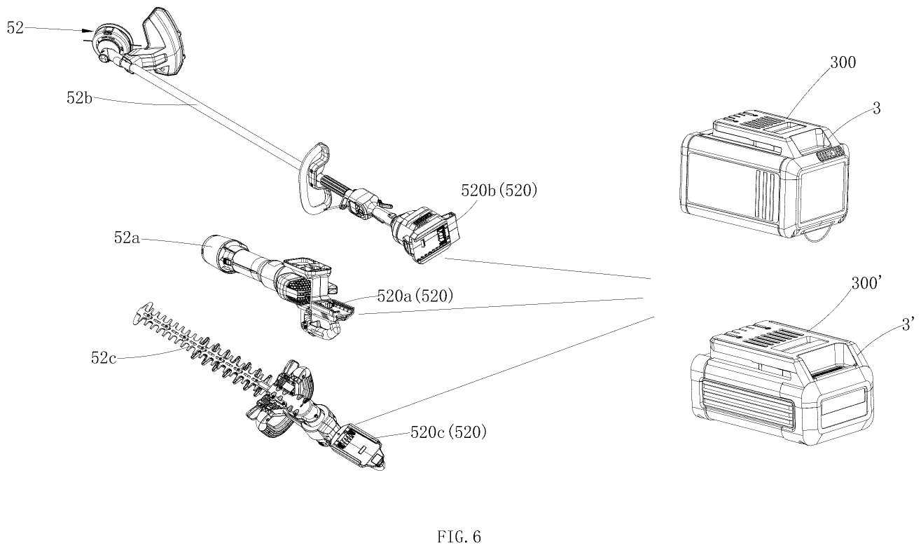

As shown in FIG. 6, the second type power tool 52 includes a battery pack mounting part 520 configured to detachably mount the second battery packs 3, 3′. When the second battery packs 3 and 3′ are mounted to the battery pack mounting part 520, the battery pack mounting part 520 reliably supports the second battery packs 3 and 3′. In other words, a plurality of different types of the second type power tools each have a battery pack mounting part having the same structure for mounting the second battery pack.

Correspondingly, the second battery pack 3, 3′ includes second mounting portions 300, 300′ respectively, and the second mounting portions 300, 300′ are configured to be detachably engaged with the battery pack mounting part 520. In other words, a plurality of different types of second battery packs each have a second mounting portion having the same structure for mounting to the second type power tool.

As shown in FIG. 6, the second type power tool 52 includes a handheld blower 52a, a lawn mower 52b, and a hedge trimmer 52c. The handheld blower 52a includes a battery pack mounting part 520a, the lawn mower 52b includes a battery pack mounting part 520b, and the hedge trimmer 52c includes a battery pack mounting part 520c, the battery pack mounting part 520a, 520b, and 520c have the same structure, and each of the second battery packs 3, 3′ is detachably mountable to the battery pack mounting part 520a, 520b, and 520c.

In the conventional techniques, the first battery pack for supplying power to the first type power tool usually adopts a cable type, and the mechanical interface and the electrical interface of the first battery pack using the cable type are respectively located in different areas on the battery pack. Usually, the mechanical interface is located on the side of the first battery pack facing the backpack device, and is used for connecting with the corresponding mechanical interface of the backpack device. And the electrical interface is located at the end of the cable provided on the first battery pack for connection with the corresponding electrical interface of the first type power tool. When the first battery pack is engaged or removed from the first type power tool, the user needs to first engage or remove the mechanical interface with the corresponding mechanical interface of the backpack device, and then connect or remove the electrical interface with the corresponding electrical interface of the first type power tool.

The second battery pack for supplying power to the second type power tool usually adopts a guide rail type. A pair of guide rails are located on the housing of the first battery pack for guiding the battery pack to be mounted to the first type power tool. At the same time, the housing of the first battery pack is also provided with a terminal for electrically connecting with the first type power tool. When the second battery pack is engaged with the second type power tool, the user only needs to slide the battery pack along a pair of guide rails, and the mechanical engaging and electrical connection are completed synchronously when the guide rails are engaged in place.

Therefore, when the cable-type first battery pack is mechanically engaged to the first type power tool, it is necessary to change the engaging method as compared with the conventional rail-type second battery pack, and the operation is troublesome.

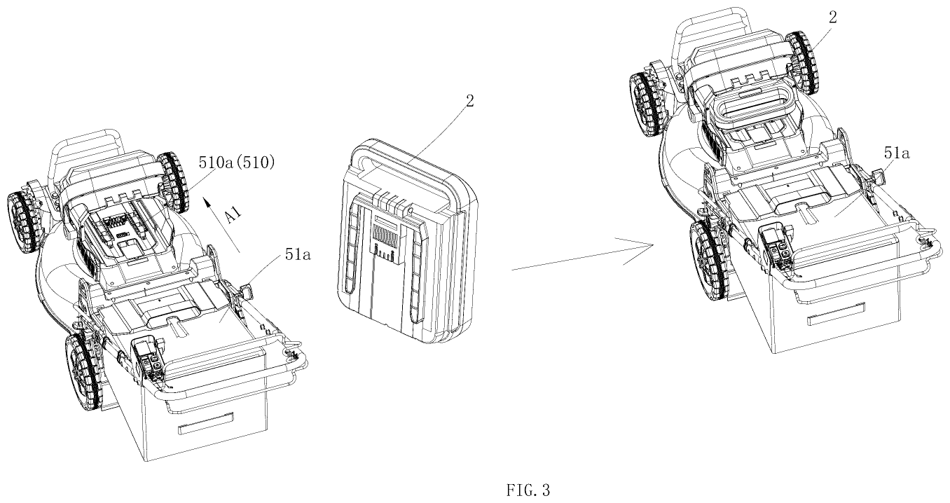

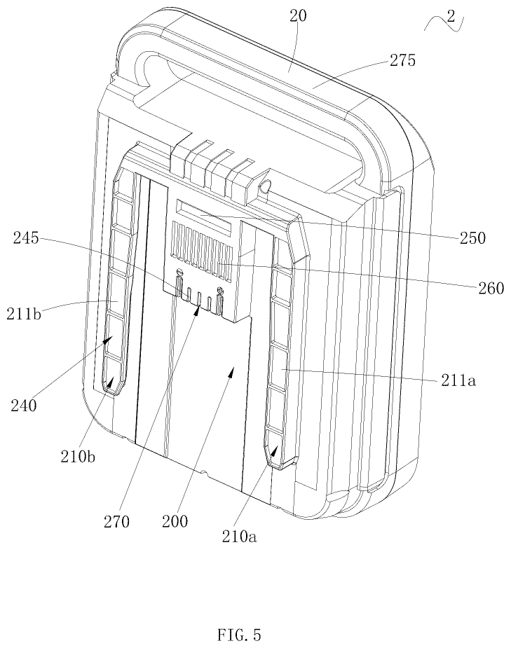

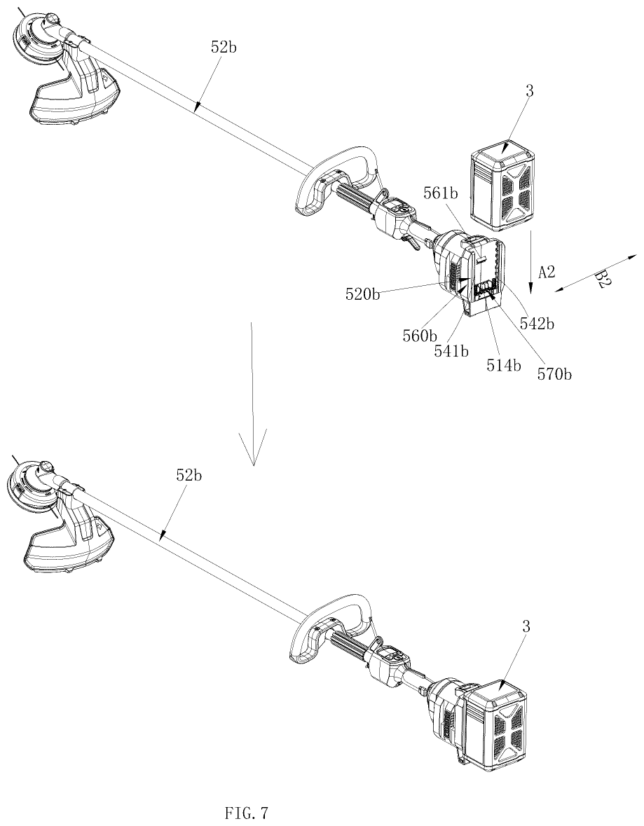

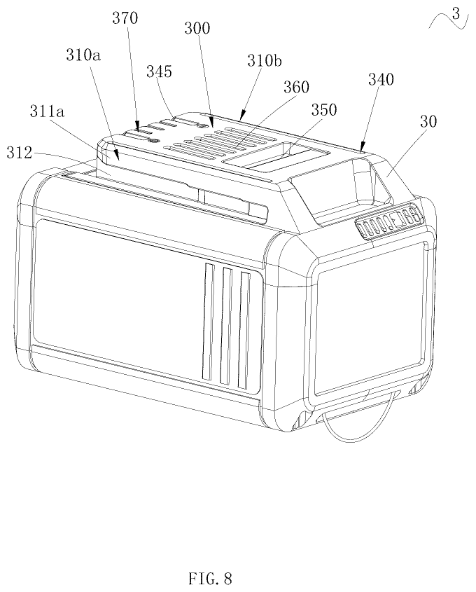

In some embodiments, as shown in FIG. 3, taking the installation of the first battery pack 2 and the lawn mower 51a as an example, the battery pack mounting portion 510a includes a first type battery pack mechanical interface 540a and a first type battery pack electrical interface 550a. As shown in FIG. 7, taking the installation of the second battery pack 3 and the lawn mower 52b as an example, the battery pack mounting part 520b includes a second type battery pack mechanical interface 560b and a second type battery pack electrical interface 570b. As shown in FIG. 5, the first mounting portion 200 includes a first mechanical interface 240 and a first electrical interface 270. As shown in FIG. 8, the second mounting portion 300 includes a second mechanical interface 340 and a second electrical interface 370. An engaging mode between the first type battery pack mechanical interface 540a and the first mechanical interface 240 is defined as a first engaging mode, and an engaging mode between the second type battery pack mechanical interface 560b and the second mechanical interface 340 is defined as a second engaging mode, and the first engaging mode is the same as the second engaging mode.

The engaging mode of the two battery packs is the same, so that when the user uses the first battery pack that needs to be carried on back, the user can use the first battery pack without changing the original engaging mode of using the second battery pack by hand, and the operation is more convenience.

It should be noted that the engaging mode includes an engaging structure and/or an engaging method, and the first engaging mode and the second engaging mode are the same, and it can be understood that the two engaging structures are the same and/or the two engaging methods are the same.

The same two kinds of engaging structures should be understood that the two kinds of engaging structures have the same shape, rather than the two kinds of engaging structures are completely identical. In the conventional techniques, the engaging structure between the battery pack and the power tool may be a sliding guide rail type, a concave-convex plug-in type, a buckle connection type, or the like. For example, the first mechanical interface and the first type battery pack mechanical interface adopts a sliding guide rail type, and the second mechanical interface and the second type battery pack mechanical interface also adopts a sliding guide rail type, but the size of the two types of sliding guide rails may be the same or different, and it should be understood that the first engaging structure and the second engaging structure are the same, so the first engaging mode and the second engaging mode are also the same.

The same two kinds of engaging methods should be understood that the engaging operations of the two engaging methods are identical. For example, the engaging method of the first mechanical interface and the first type battery pack mechanical interface adopts sliding engaging method, and the engaging method of the second mechanical interface and the second type battery pack mechanical interface also adopts sliding engaging method, and the operation sequence and operation mode of the two kinds of sliding engage are the same, which can be understood that the first engaging method and the second engaging method are the same, so the first engaging mode and the second engaging mode are also the same.

Furthermore, when the cable-type first battery pack is mounted to the first type power tool, the mechanical connection and the electrical connection cannot be completed synchronously and simultaneously, and the operation is complicated and the work efficiency is low. In some embodiments, when the first battery pack 2 is mounted to the battery pack mounting portion 510, the first battery pack 2 supplies power the first type power tool 51; And/or when the second battery pack 3 is mounted to the battery pack mounting part 520, the second battery pack 3 supplies power to the second type power tool 52. The battery pack can be directly mounted on the corresponding power tool to realize power supply, in other words, when the battery pack and the power tool are mechanically connected, the electrical connection is also completed at the same time, and there is no need to complete the mechanical connection and electrical connection step by step, which is convenient to operate, thereby improving work efficiency.

Specifically, the first electrical interface 270 is electrically connected to a first type battery pack electrical interface 550a when the first mechanical interface 240 is engaged with the first type battery pack mechanical interface 540a; and/or, the second electrical interface 370 is electrically connected to a second type battery pack electrical interface 570b when the second mechanical interface 340 is engaged with the second type battery pack mechanical interface 560b.

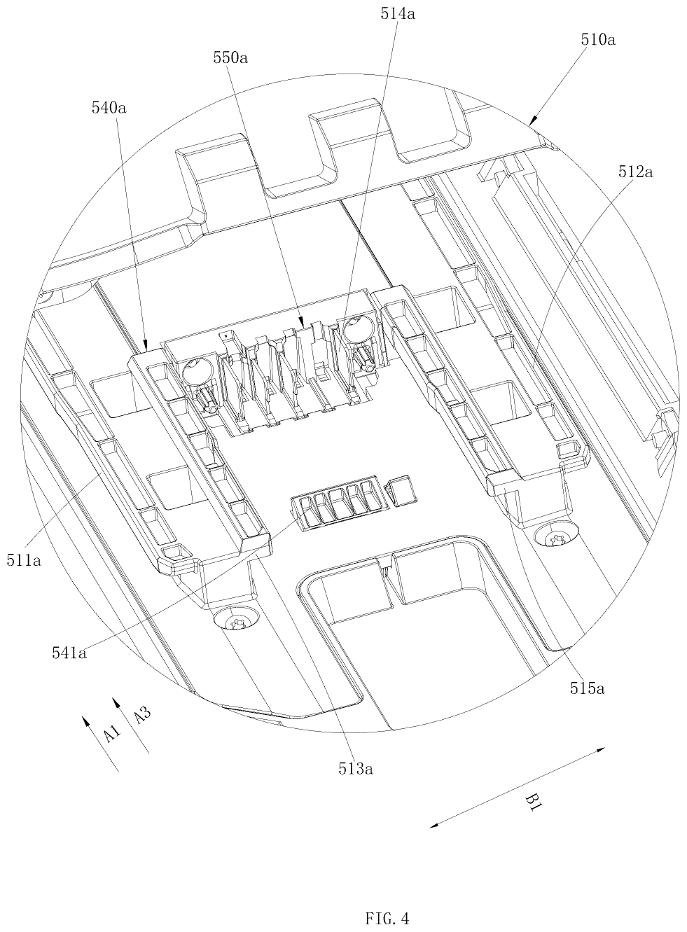

In some embodiments, as shown in FIGS. 3 and 4, the first type battery pack mechanical interface 540a includes a pair of first guiding portions 511a and 512a, and the first guiding portions 511a and 512a are configured to guide the first battery pack 2 to be slidably mounted to the lawn mower 51a in the engaging direction A1. Of course, the first battery pack 2 may also be slidably removed from the lawn mower 51a in a direction opposite to the engaging direction A1. As an example, the engaging direction A1 is configured as the extending direction of the first guiding portions 511a and 512a.

Correspondingly, as shown in FIG. 5, the first mechanical interface 240 includes a pair of first engaging portions 210a and 210b, and the pair of first engaging portions 210a and 210b are configured to engage with the pair of first guiding portions 511a and 512a respectively, to realize sliding connection between the lawn mower 51a and the first battery pack 2. It should be noted that, since the first guiding portion and the first engaging portion are in a mutually engaged relationship, the engaging direction A1 may be understood as an extending direction of the first engaging portion.

In some embodiments, as shown in FIG. 7, the second type battery pack mechanical interface 560b includes a pair of third guiding portions 541b and 542b, and the third guiding portions 541b and 542b are configured to guide the second battery pack 3 to be slidably mounted to the lawn mower 52b in the engaging direction A2. Of course, the second battery pack 3 may also be slidably removed from the lawn mower 52b in a direction opposite to the engaging direction A2. The engaging direction A2 is configured as the extending direction of the third guiding portions 541b and 542b.

Correspondingly, the second mechanical interface 340 includes a pair of second engaging portions 310a, 310b, and the pair of second engaging portions 310a, 310b are configured to engage with the pair of third guiding portions 541b, 542b respectively, so as to realize the sliding connection between the lawn mower 52b and the second battery pack 3. It should be noted that, since the third guiding portion and the second engaging portion are in a mutually engaged relationship, the engaging direction A2 may be understood as an extending direction of the second engaging portion.

The first battery pack and/or the second battery pack are mechanically engaged to the power tool by a sliding engaging method, which does not change the usage habit of users who usually use the power tool by hand, and is more convenient than the cable-type battery pack.

In some embodiments, as shown in FIG. 4, the first type battery pack mechanical interface 540a further includes a locking member 541a, and as shown in FIG. 5, the first mechanical interface 240 further includes a first locking portion 250. The locking member 541a engages with the first locking portion 250 to lock the first type power tool and the first battery pack when the first type battery pack mechanical interface 540a is engaged with the first mechanical interface 240.

In some embodiments, as shown in FIG. 7, the second type battery pack mechanical interface 560b further includes a second locking member 561b, and as shown in FIG. 8, the second mechanical interface 340 further includes a second locking portion 350. The second locking member 561b engages with the second locking portion 350 to lock the second type power tool and the second battery pack when the second type battery pack mechanical interface 560b is engaged with the second mechanical interface 340.

As an example, in the width direction B1 perpendicular to the engaging direction A1, the locking member 541a is located between the pair of first guiding portions 511a and 512a, and the first locking portion 250 is located between the pair of first engaging portions 210a and 210b. In the width direction B2 perpendicular to the engaging direction A2, the second locking member 561b is located between the pair of third guiding portions 541b and 542b, and the second locking portion 350 is located between the pair of second engaging portions 310a and 310b. The locking member 541a and the second locking member 561b are configured as snaps, and the first locking portion 250 and the second locking portion 350 are configured as slots.

It should be noted that, taking the engaging between the first battery pack 2 and the first type power tool 51a as an example, even when the first locking portion 250 is disengaged from the locking member 541a, the first mechanical interface 240 is still in an engaging state with the first type battery pack mechanical interface 540a due to the engaging connection between the first guiding portion 511a and 512a and the first engaging portion 210a and 210b. In this way, the battery pack is avoided from being directly separated from the power tool when the user unlocks by mistake, so that the battery pack is avoid damage caused by the battery pack falling off from the battery pack mounting portion.

The first type battery pack electrical interface 550a includes a plurality of device terminals 514a for electrically connecting with corresponding terminals of the first electrical interface to enable powering the first type power tool. The device terminal 514a is configured to be electrically connected to a corresponding terminal of the first battery pack 2 when the first mounting portion 200 is engaged to the battery pack mounting portion 510a. In this way, the mechanical engaging and the electrical connection can be synchronized, and the operation efficiency is high. As an example, the device terminal 514a is located between the pair of first guiding portions 511a and 512a in the width direction B1 perpendicular to the engaging direction A1.

The second type battery pack electrical interface 570b includes a plurality of tool terminals 514b for electrical connection with corresponding terminals of the second electrical interface to enable powering the second type power tool. Similarly, for convenience of operation, the tool terminal 514b is configured as, when the second mounting portion 300 is engaged with the battery pack mounting part 520b, the tool terminal 514b is electrically connected to the corresponding terminal of the second battery pack 3. As an example, the tool terminal 514b is located between the pair of third guiding portions 541b, 542b in the width direction B2 perpendicular to the engaging direction A2.

As described above, in order to provide a long endurance for the first type power tool, the capacity of the first battery pack is larger than the capacity of the second battery pack. At the same time, the weight of the first battery pack is also greater than the weight of the second battery pack. Also as described above, since the user of the commercial garden tool cannot hold a battery pack having a weight of greater than or equal to 3.6 Kg for a long time by hand, the first battery pack 2 is configured to be carried on back by the user, and the weight of the first battery pack is greater than or equal to 3.6 Kg. Further, the weight range of the first battery pack is 4-12 Kg, for example, 4 Kg, 5 Kg, 8 Kg, 10 Kg or other.

The second mounting portion 300 is different from the first mounting portion 200. The second mounting portion 300 is configured to be detachably engaged with the battery pack mounting part 520 and cannot be engaged with the battery pack mounting portion 510. In this way, the first battery pack can be reliably engaged to the first type power tool, and if the first battery pack is engaged to the second type power tool, the center of gravity is unstable due to excessive weight of the first battery pack, and the first battery pack is damaged by falling.

In some embodiments, the ratio of the weight of the first battery pack to the weight of the second type power tool is 0.5-4. In one embodiment, the weight of the first battery pack is 4 Kg, the weight of the second type power tool is 8 Kg, and the ratio of the two is 0.5; In one embodiment, the weight of the first battery pack is 5 Kg, the weight of the second type power tool is 2.5 Kg, and the ratio of the two is 2; In one embodiment, the weight of the first battery pack is 6 Kg, the weight of the second type power tool is 4 Kg, and the ratio of the two is 1.5; In one embodiment, the weight of the first battery pack is 8 Kg, the weight of the second type power tool is 2 Kg, and the ratio of the two is 4.

Since the ratio of the weight of the first battery pack to the weight of the second type power tool is large, if the first battery pack is mounted on the second type power tool, the center of gravity is unstable when the user holds the second type power tool by hand, and the first battery pack is damaged by falling from the second type power tool.

In some embodiments, the ratio of the length of the first guiding portion 511a, 512a to the length of the third guiding portion 541b, 542b ranges from 1.5 to 2; and/or, a ratio of the maximum distance between the pair of first guiding portions 511a, 512a and the maximum distance between the pair of third guiding portions 541b, 542b ranges from 1.5 to 2.5. This arrangement can ensure that the strength of the mechanical interface of the first type battery pack is greater than the strength of the mechanical interface of the second type battery pack, thereby ensuring reliable installation.

It should be noted that, the length of the first guiding portions 511a and 512a refers to the maximum dimension of the first guiding portions 511a and 512a in the engaging direction A1, the length of the third guiding portions 541b and 542b refers to the maximum dimension of the third guiding portions 541b and 542b in the engaging direction A2, the maximum distance between the pair of first guiding portions 511a and 512a refers to the dimension in the width direction B1, and the maximum distance between the pair of third guiding portions 541b and 542b refers to the dimension in the width direction B2.

In some embodiments, in order to achieve communication compatibility of different types of power tools, the first type battery pack electrical interface 550 and the second type battery pack electrical interface 570 are the same. Correspondingly, the first electrical interface 270 and the second electrical interface 370 are the same. Specifically, the type, arrangement, and number of the device terminals 514a and the tool terminals 514b are the same. Accordingly, the type, arrangement, and number of the terminals of the first battery pack and the terminals of the second battery pack are also the same.

In some embodiments, the second battery pack is also configured to be detachably mounted to the first type power tool to cause the second battery pack to power the first type power tool. The first type power tool can be adapted to the first battery pack and the second battery pack with two different interfaces, which is beneficial to realize the versatility of the battery pack.

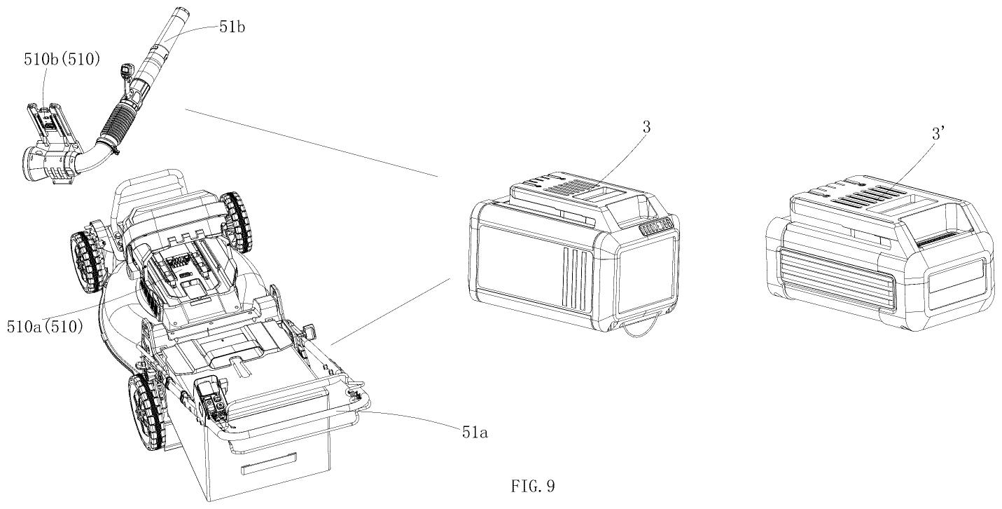

As shown in FIG. 9, each of the second battery packs 3 and 3′ can be detachably mounted to the lawn mower 51a or the backpack blower 51b so that the second battery packs 3 and 3′ supply power to the lawn mower 51a or the backpack blower 51b.

Specifically, the battery pack mounting portion 510 is configured to detachably engage with the second mounting portion 300 and 300′, When the second battery pack 3, 3′ is mounted to the battery pack mounting portion 510, the second battery pack 3, 3′ supplies power to the first type power tool 51.

In some embodiments, when the battery pack mounting portion 510 is engaged with one of the first mounting portion 200 or the second mounting portion 300, the other of the first mounting portion 200 or the second mounting portion 300 cannot be engaged with the battery pack mounting portion 510. This arrangement can save the space of the battery pack mounting portion, and the structure of the battery pack mounting portion is more compact.

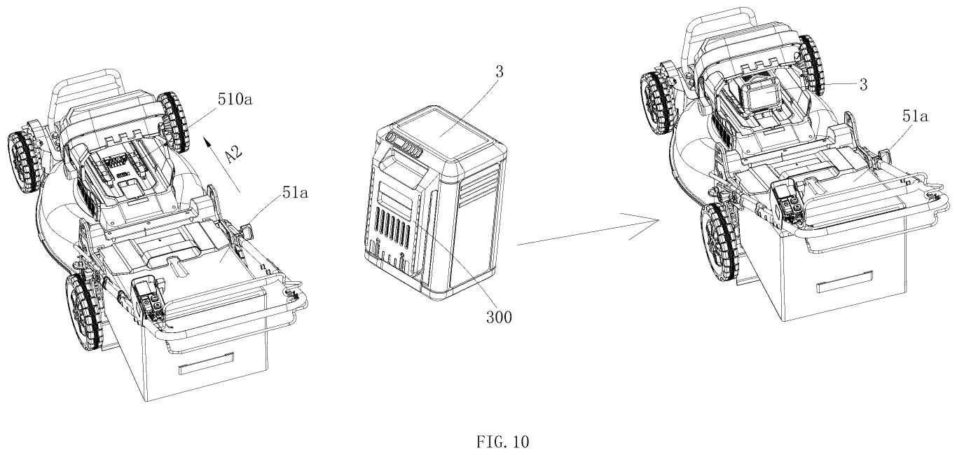

Taking the installation of the second battery pack 3 to the lawn mower 51a as an example, as shown in FIG. 4 and FIG. 10, the battery pack mounting portion 510a includes a pair of second guiding portions 513a and 515a extending in an engaging direction A3 for guiding the second battery pack 3 to be slidably engaged to the lawn mower 51a in the engaging direction A3. Of course, the second battery pack 3 may also be slidably removed from the lawn mower 51a in a direction opposite to the engaging direction A3. As an example, the engaging direction A3 is parallel to the engaging direction A1.

Since the second guiding portion and the third guiding portion are both used to guide the engaging of the second battery pack, the size and the shape of the second guiding portion and the third guiding portion are the same.

Further, the device terminal 514a is further configured to be electrically connected to a corresponding terminal of the second battery pack 3 when the second battery pack 3 is engaged with the second type power tool 51a. Such arrangement enables that device terminal to be adapted to the corresponding terminal of the two kinds of battery packs, and the structure is simple and compact, thereby enabling the miniaturization of the mounting portion of the battery packs.

In the above embodiment, the first battery pack or the second battery pack is directly mounted to the wheeled power tool, and the user does not need to carry the battery pack on back when the wheeled power tool is working. Moreover, the battery pack can be directly mounted on the power tool to realize power supply to the power tool, mechanical connection and electrical connection are simultaneously and synchronously completed, and the operation is convenient.

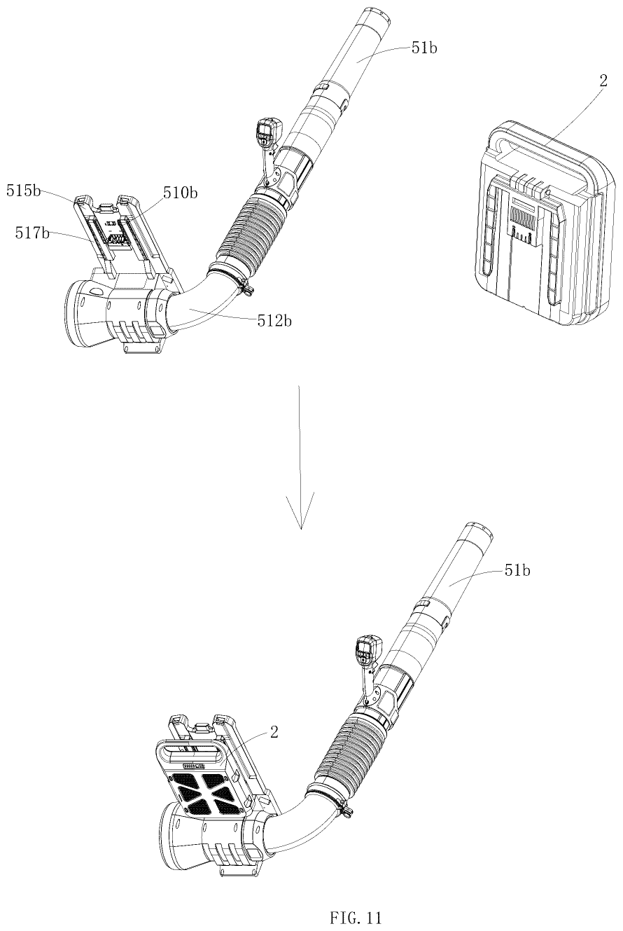

In some embodiments, a user needs to carry a first battery pack on back when working with a backpack power tool. Taking the installation of the first battery pack 2 and the backpack blower 51b as an example, as shown in FIG. 11, the backpack blower 51b further includes a main body 512b and a back frame 515b connected to the main body 512b. The back frame is configured for a user to carry the backpack blower 51b on back, and the first battery pack 2 configured to be detachably mounted to the back frame 515b so that the first battery pack 2 supplies power to the backpack blower 51b.

Specifically, the back frame 515b is located at one end of the main body 512b, and is detachably connected or fixedly connected to the main body 512b. The back frame 515b includes a support plate 517b and a strap (not shown) and/or a waistband (not shown) connected to the support plate 517b. The back frame 515b includes a battery pack mounting portion 510b, and the battery pack mounting portion 510b is located on the support plate 517b. When the user needs to use the backpack blower 51b, the first battery pack 2 can be mounted on the back frame 515b, and the back frame 515b realizes that the user carries the backpack blower 51b, and carries the battery pack through the back and/or waist of the user, thereby reducing the stress on the hands of the user and enabling the user to use the battery pack more comfortably.

In order to enable the battery pack system to be alternately powered, in some embodiments, the second battery pack is also configured to be detachably mounted to the back frame 515b, and the second battery packs 3 and 3′ are each detachably mountable to the battery pack mounting portion 510b to enable the second battery packs 3 and 3′ to power the backpack blower 51b.

Specifically, the structure of the battery pack mounting portion 510b may refer to the structure of the battery pack mounting portion 510a, and will not be repeatedly described here.

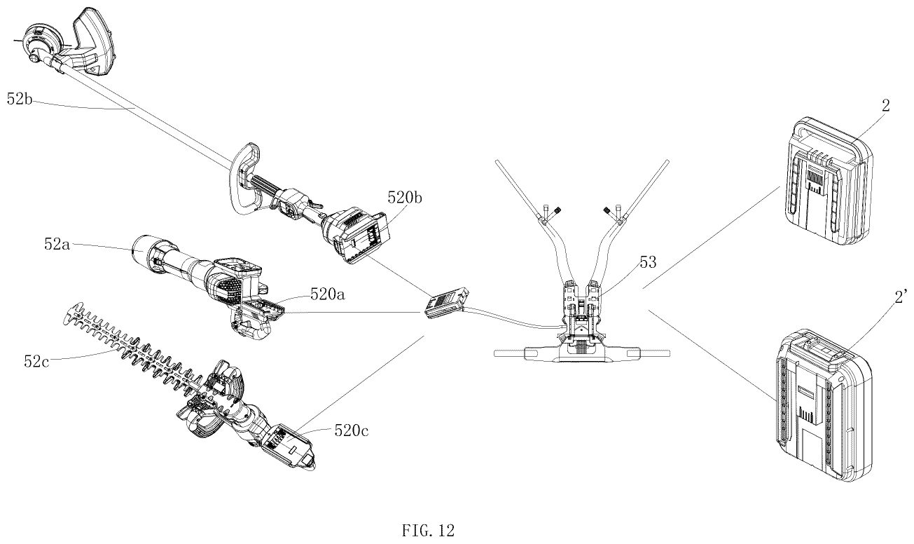

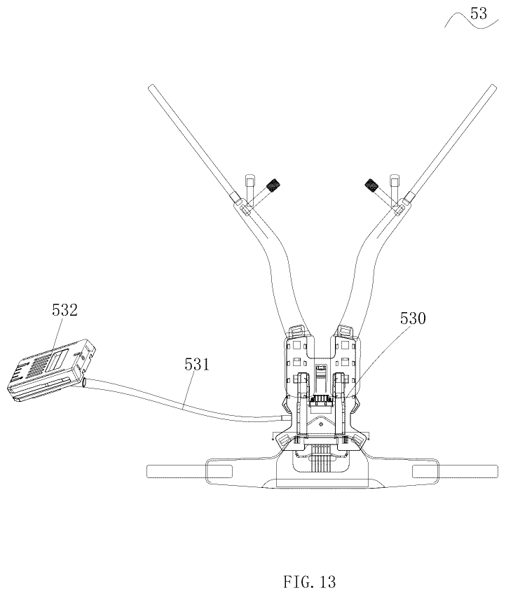

In some embodiments, the first battery pack can also supply power to the second type power tool by carrying it on back, which not only solves the problem of handheld discomfort due to the excessive weight of the first battery pack, but also realizes the versatility of the battery pack. As shown in FIG. 12, each of the first battery packs 2 and 2′ is capable of supplying power to the hand-held blower 52a, the lawn mower 52b, and the hedge trimmer 52c. Taking the first battery pack 2 supplying power to the lawn mower 52b as an example, as shown in FIG. 13, the electrical system 5 further includes a backpack device 53 configured to be carried on back by a user, the backpack device 53 including a cable 531, a plug 532 and a backpack mounting portion 530, the cable 531 is configured to connect the plug 532 and the backpack mounting portion 530, the backpack mounting portion 530 is configured to detachably mount the first battery pack 2, the plug 532 is configured to detachably engage the battery pack mounting part 520b, the first battery pack powering the lawn mower 52b when the battery pack mounting part 520b is engaged to the plug 532 and the first battery pack 2 is mounted to the backpack mounting portion 530.

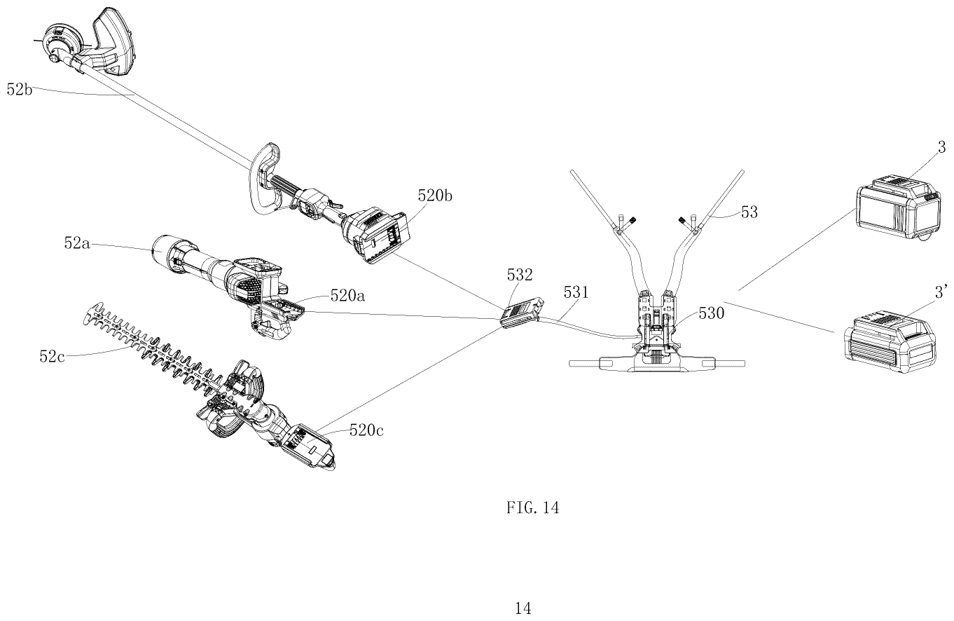

In some embodiments, in order to meet the needs of some users who prefer to carry the battery pack on their back, the second battery pack can also be implemented to power the second type power tool by the backpack device. As shown in FIG. 14, each of the second battery packs 3, 3′ is capable of supplying power to a hand-held blower 52a, a lawn mower 52b, and a hedge trimmer 52c by a backpack device 53. Taking the second battery pack 3 supplies power to the lawn mower 52b by the backpack device 53 as an example, the backpack mounting portion 530 is configured to detachably mount the second battery pack 3, the plug 532 is configured to detachably engage the battery pack mounting part 520b, and the second battery pack 3 supplies power to the lawn mower 52b when the lawn mower 52b is engaged to the plug 532 and the second battery pack 3 is mounted to the backpack mounting portion 530.

By providing a backpack mounting portion on the backpack device where the first battery pack or the second battery pack can be mounted, a new backpack device is avoided, and the cost can be saved.

In order to be compact, the structure of the plug 532 is configured to be substantially the same as that of the second mounting portion 200, and the structure of the backpack mounting portion 530 is configured to be substantially the same as that of the battery pack mounting portions 510a and 510b, and will not be described herein.

Since the electrical system provided in the present application mainly serves commercial landscape operations, a power tool needs to complete enough work per unit time and needs to continuously work during a working time of one day. Correspondingly, this requires a continuous energy supply for the power tools. In other words, the power tool can be used continuously or over the course of the day. In addition to improving the working efficiency by using a high-power power tool, according to another aspect, an energy replenishing time of the power tool also needs to be reduced. Therefore, the power tool does not need to wait for energy, that is, energy is continuously supplied to the power tool, so that the power tool continuously works.

Based on this, a limited quantity of battery packs is equipped for the power tool system according to the use scenarios of the commercial garden power tools and a quantity of workers on a garden team. The plurality of battery packs may perform charging and discharging in turn to supply power to the power tool system, so that the use costs of the electric system are relatively low, and it is convenient to carry a relatively small quantity of battery packs. This requires a sufficiently high charging speed of the battery pack. Before a battery pack on the power tool is discharged or when the battery pack has been discharged, a backup charging battery pack may be fully charged.

In order to meet the above requirements, in some embodiments, the first battery pack includes a plurality of first battery cells, the second battery pack includes a plurality of second battery cells, the continuous charging rate of each first battery cell is configured such that the ratio of the charging time to the discharging time of the first battery cell is 0.7-1.5; and/or, the continuous charging rate of each second battery cell is configured such that the ratio of the charging time to the discharging time of the second battery cell is 0.7-1.5. This makes the charging time and discharging time of the battery pack basically the same, and the battery pack can be recycled as soon as possible, thus providing long endurance for power tools.

In some embodiments, in order to support fast charging, the continuous charging rate of each first battery cell is greater than 3C; and/or, the continuous charging rate of each second battery cell is greater than 3C. Further, the continuous charging rate of the first battery cell and/or the continuous charging rate of the second battery cell may reach 3C-20C. In other words, the continuous charging rate of the first battery cell and/or the continuous charging rate of the second battery cell may be 3C, 4C, 5C, 6C, 7C, 8C, 9C, 10C, 11C, 12C, 15C, or 20C. It may be understood that the continuous charging rate of the battery pack is used for identifying a capability of the battery pack and does not mean that the battery pack is necessarily charged with the capability. In other words, the battery pack may also be charged at a charging rate of less than the capability. This may be specifically determined based on an actual situation.

Since the user's ability to hold and carry on back is limited, the weight of the first battery pack and the second battery pack should not be too large, but the first battery pack and the second battery pack also need sufficient power to ensure the long endurance of the power tool, so the first battery pack and the second battery pack need to store sufficient power per unit mass. In some embodiments, the ratio of the rated energy to the weight of the first battery pack is in a range of 60-300 Wh/Kg; and/or, the ratio of the rated energy to the weight of the second battery pack is in a range of 60-300 Wh/Kg. Further, the ratio of rated energy to weight of the first battery pack and/or the second battery pack is in a range of 80-200 Wh/Kg, for example, 80 Wh/Kg, 100 Wh/Kg, 200 Wh/Kg, or otherwise.

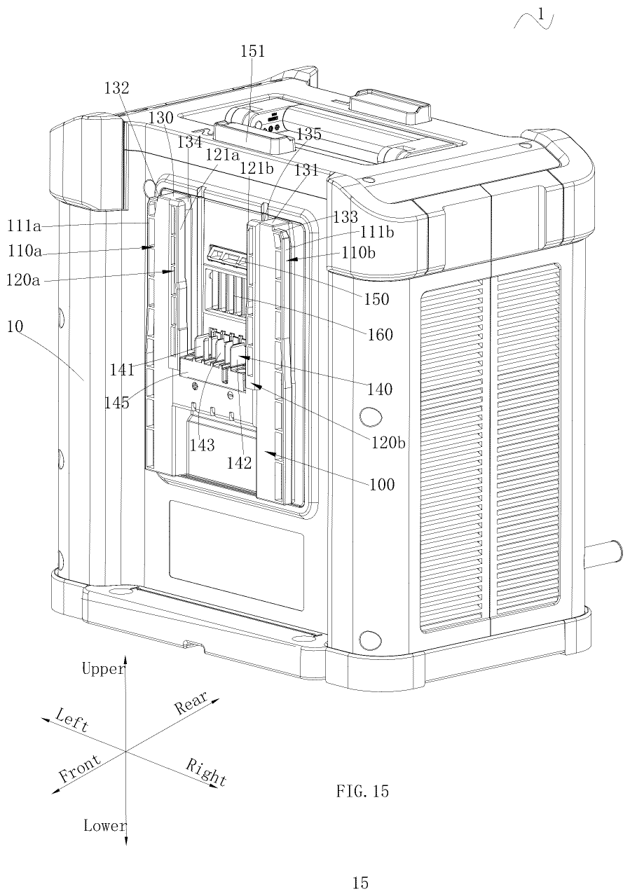

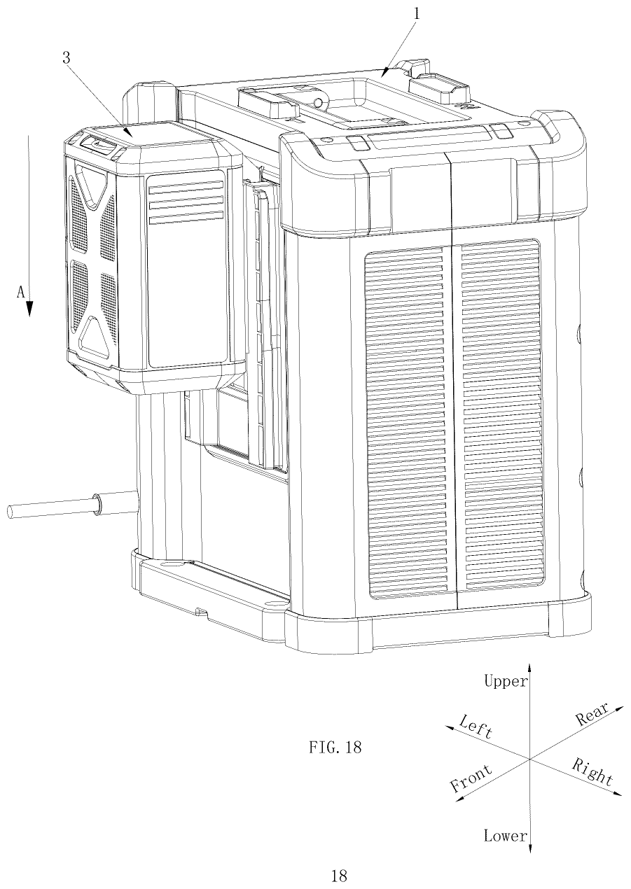

Referring to FIG. 15 to FIG. 18, the electrical system 5 further includes an electrical device 1.

In some embodiments, as shown in FIG. 15, the electrical device 1 is configured as a charger, when the first battery pack 2 or the second battery pack 3 engages with the electrical device 1, the electrical device 1 can charge the first battery pack 2 or the second battery pack 3.

The electrical device 1 includes a device housing 10, using FIG. 15 as an example, front-to-back, upper-to-lower, and left-to-right directions in the electrical device 1 are defined, a lengthwise extension direction of the device housing 10 in the state shown in FIG. 15 is defined as the upper-to-lower direction, and a width direction of the device housing 10 is defined as the left-to-right direction, the front-to-back direction is perpendicular to both the left-to-right direction and the upper-to-lower direction.

The electrical device 1 includes a battery pack mounting portion 100, the battery pack mounting portion 100 is arranged on the device housing 10 and configured to detachably engage with the first battery pack 2 or the second battery pack 3.

In some embodiments, similar to the aforementioned battery pack mounting portion 510, when one of the first battery pack 2 or the second battery pack 3 is mounted to the battery pack mounting portion 100, the other of the first battery pack 2 or the second battery pack 3 cannot be mounted to the battery pack mounting portion 100.

In some embodiments, the specific structure of the battery pack mounting portion 100 is the same as the specific structure of the battery pack mounting portion 510 described above, and both of them can be detachably engaged with the first battery pack 2 or the second battery pack 3, thereby realizing that the electrical device can be adapted to both battery packs.

In some embodiments, the electrical device 1 includes two battery pack mounting portions 100 arranged oppositely in the front-to-back direction, the two battery pack mounting portions 100 are of the same structure, and each can be engaged with the first battery pack 2 or the second battery pack 3.

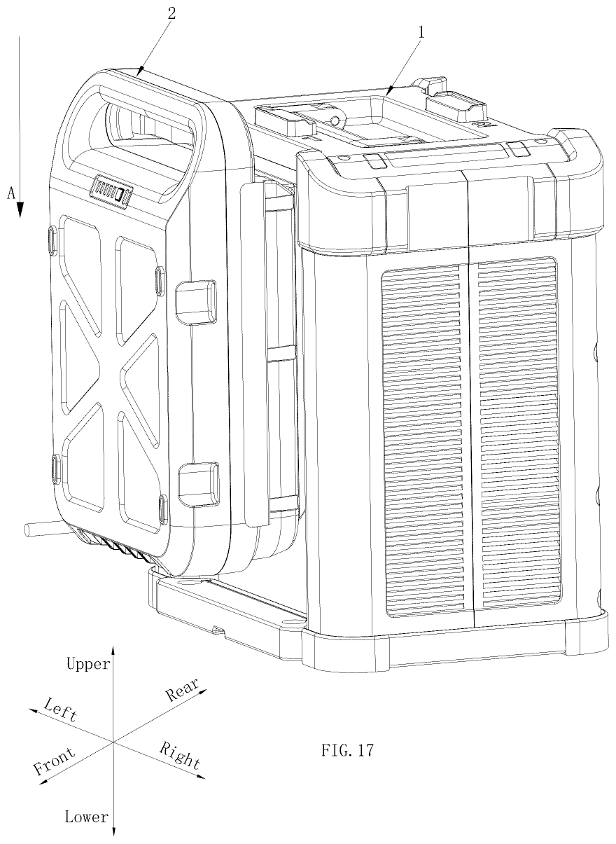

The battery pack mounting portion 100 includes a pair of first guiding portions 110a and 110b and a pair of second guiding portions 120a and 120b, the first guiding portions 110a and 110b are configured to guide the first battery pack 2 to engage with the electrical device 1 in an engaging direction A, the second guiding portions 120a and 120b are configured to guide the second battery pack 3 to engage with the electrical device 1 in the engaging direction A, the first guiding portions 110a and 110b and the second guiding portions 120a and 120b are independent of each other, and in a width direction perpendicular to the engaging direction A, the pair of first guiding portions 110a and 110b are located on two sides of the pair of second guiding portions 120a and 120b. In some embodiments, as shown in FIG. 17, the engaging direction A is set to be lower in the upper-to-lower direction, and the width direction is set to be the left-right direction.

It should be noted that “The first guiding portion and the second guiding portion are independent of each other” is understood as follows: A function of the first guiding portion and a function of the second guiding portion are independent of each other, in other words, a function of the first guiding portion for guiding the first battery pack 2 to engage with the electrical device 1 in the engaging direction A and a function of the second guiding portion for guiding the second battery pack 3 to engage with the electrical device 1 in the engaging direction A do not intersect each other.

In addition, “the pair of first guiding portions 110a and 110b are located on two sides of the pair of second guiding portions 120a and 120b” is understood as follows: One first guiding portion 110a of the pair of first guiding portions is located on an outer side of one second guiding portion 120a of the pair of second guiding portions, the other first guiding portion 110b of the pair of first guiding portions is located on an outer side of the other second guiding portion 120b of the pair of second guiding portions, and a spacing between the pair of first guiding portions 110a and 110b is greater than a spacing between the pair of second guiding portions 120a and 120b.

As shown in FIG. 5 and FIG. 17, the first battery pack 2 slides from top to bottom along the pair of first guiding portions 110a and 110b, so that the first battery pack 2 engages with the electrical device 1; and the second battery pack 3 slides from top to bottom along the pair of second guiding portions 120a and 120b, so that the second battery pack 3 engages with the electrical device 1. Similarly, the first battery pack 2 slides from bottom to top along the pair of first guiding portions 110a and 110b, so that the first battery pack 2 disengages from the electrical device 1; and the second battery pack 3 slides from bottom to top along the pair of second guiding portions 120a and 120b, so that the second battery pack 3 disengages from the electrical device 1.

The electrical device 1 can adapt to battery packs with two different interface sizes, to facilitate universality of the electrical device 1, and the size of the battery pack mounting portion 100 is reduced, to facilitate miniaturization of the electrical device 1.

Further, the pair of first guiding portions 110a and 110b are spaced apart from each other in the width direction, the pair of second guiding portions 120a and 120b are also spaced apart from each other in the width direction, and both the pair of first guiding portions 110a, 110b and the pair of second guiding portions 120a and 120b extend in the engaging direction A.

In some embodiments, the sizes of the pair of first guiding portions 110a and 110b in the engaging direction A are the same, and the sizes of the pair of second guiding portions 120a and 120b in the engaging direction A are the same.

In some embodiments, a center line of the pair of first guiding portions 110a and 110b coincides with a center line of the pair of second guiding portions 120a and 120b. Specifically, the pair of first guiding portions 110a and 110b and the pair of second guiding portions 120a and 120b are arranged symmetrically along a center line of the device housing 10.

In some embodiments, the pair of first guiding portions 110a and 110b and the pair of second guiding portions 120a and 120b at least partially overlap in the engaging direction A. In such an arrangement, the size of the battery pack mounting portion 100 can be reduced, to facilitate miniaturization of the electrical device 1.

In some embodiments, projection regions of the pair of second guiding portions 120a and 120b on a plane perpendicular to the width direction are located within projection regions of the pair of first guiding portions 110a and 110b on the plane perpendicular to the width direction.

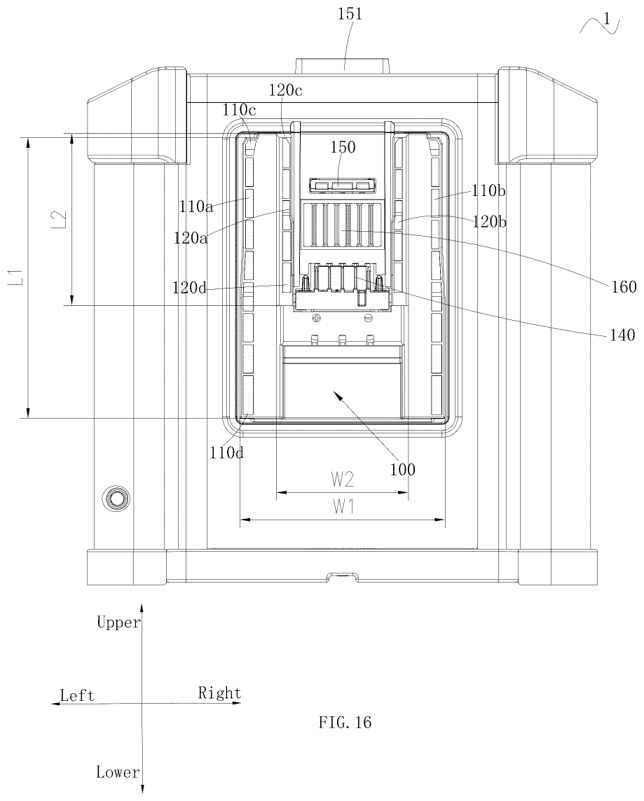

In some embodiments, as shown in FIG. 16, in the engaging direction A, the second guiding portions 120a and 120b do not exceed a region range defined by the first guiding portions 110a and 110b.

In some embodiments, in the engaging direction A, a ratio of a length L1 of the first guiding portions 110a and 110b to a length L2 of the second guiding portions 120a and 120b ranges from 1.5 to 2. In such an arrangement, the battery pack can be easily plugged into and unplugged from the electrical device while ensuring the structural strength of the guiding portions. In some embodiments, in the engaging direction, the length L1 of the first guiding portions 110a and 110b is 211 mm, and the length L2 of the second guiding portions 120a and 120b is 120 mm, in this case, the ratio of the length L1 of the first guiding portions 110a and 110b to the length L2 of the second guiding portions 120a and 120b is about 1.76.

In some embodiments, in the width direction, a ratio of a maximum distance W1 between the pair of first guiding portions 110a and 110b to a maximum distance W2 between the pair of second guiding portions 120a and 120b ranges from 1.5 to 2.5, in such an arrangement, the battery pack can be easily plugged into and unplugged from the electrical device while ensuring the structural strength of the guiding portions. In some embodiments, the maximum distance W1 between the pair of first guiding portions 110a and 110b is 135 mm, and the maximum distance W2 between the pair of second guiding portions 120a and 120b is 76 mm, in this case, the ratio of the maximum distance W1 between the pair of first guiding portions 110a and 110b to the maximum distance W2 between the pair of second guiding portions 120a and 120b is about 1.78.

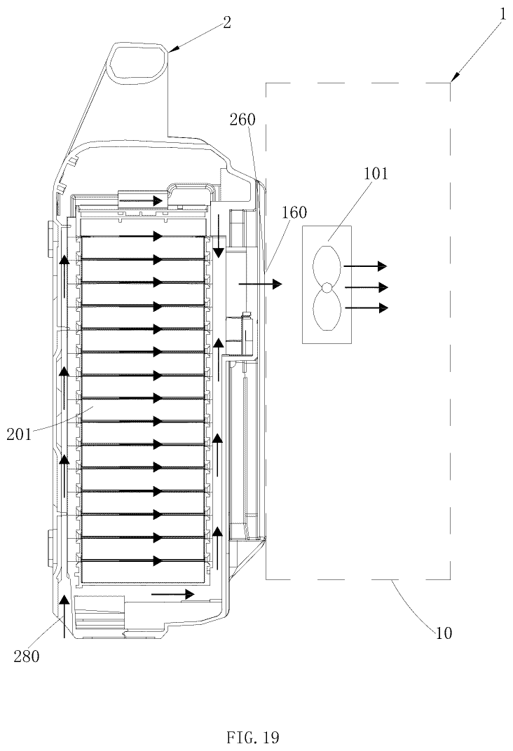

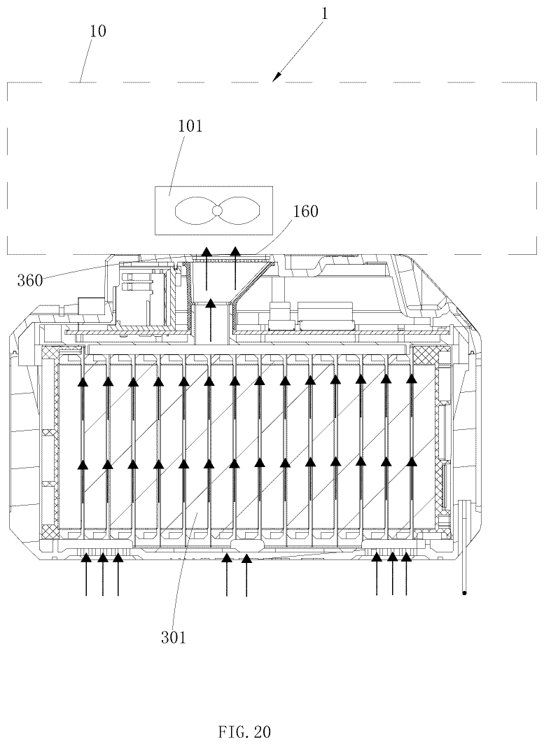

Correspondingly, as shown in FIG. 5 and FIG. 19, the first battery pack 2 includes a first housing 20, at least one first battery cell 201 accommodated in the first housing 20. A first mounting portion 200 is arranged on the first housing 20, the first mounting portion 200 includes a pair of first engaging portions 210a and 210b, the pair of first engaging portions 210a and 210b are configured to engage with the pair of first guiding portions 110a and 110b respectively, to implement engaging between the electrical device 1 and the first battery pack 2. As shown in FIG. 6 and FIG. 20, the second battery pack 3 includes a second housing 30, at least one second battery cell 301 accommodated in the first housing 20. A second mounting portion 300 is arranged on the second housing 30, the second mounting portion 300 includes a pair of second engaging portions 310a and 310b, the pair of second engaging portions 310a and 310b are configured to engage with the pair of second guiding portions 120a and 120b respectively, to implement engaging between the electrical device 1 and the second battery pack 3.

Since the first engaging portions 210a and 210b are engaged to the first guiding portions 110a and 110b, and the second engaging portions 310a and 310b are engaged to the second guiding portions 120a and 120b, the shapes and dimensions of the first engaging portions 210a and 210b and the first guiding portions 110a and 110b are matched with each other, and the shapes and dimensions of the second engaging portions 310a and 310b are matched with each other. In some embodiments, in the engaging direction A, the ratio of the length of the first engaging portion 210a, 210b to the length of the second engaging portion 310a, 310b ranges from 1.5 to 2. In some embodiments, in the width direction, the ratio of the maximum distance between the pair of first engaging portions 210a, 210b to the maximum distance between the pair of second engaging portions 310a, 310b ranges from 1.5 to 2.5.

It should be noted that the first guiding portion, the second guiding portion, the first engaging portion, and the second engaging portion may also be other engaging forms. The first guiding portion, the second guiding portion, the first engaging portion, and the second engaging portion are not limited by feature shapes and sizes.

As shown in FIG. 16, in the engaging direction A, a size L2 of the second guiding portions 120a and 120b is less than a size L1 of the first guiding portions 110a and 110b, the first guiding portions 110a and 110b have an engaging beginning end 110c and an engaging tail end 110d that are oppositely arranged in the engaging direction A, the second guiding portions 120a and 120b have an engaging beginning end 120c and an engaging tail end 120d that are oppositely arranged in the engaging direction A, both the first battery pack 2 and the second battery pack 3 come, when engaging with the electrical device 1, into contact with the engaging beginning ends 110c and 120c earlier than the engaging tail ends 110d and 120d, and the engaging tail end 120d of the second guiding portion is closer to the engaging beginning end 110c of the first guiding portion than the engaging tail end 110d of the first guiding portion. In this way, the second battery pack 3 can engage with the electrical device 1 in place earlier than the first battery pack 2, thereby avoiding a case that the second battery pack 3 cannot be easily removed from the electrical device when a shell or another shelter is arranged outside an engaging region of the electrical device.

Under a specific voltage, when energy of the battery pack is larger, capacity of the battery pack is larger, a quantity of cells arranged in the battery pack is larger, a weight of the battery pack is larger, and a loading area required by the electrical device to be connected to the battery pack is larger. However, a loading area provided on the electrical device should not be excessively large. Otherwise, sizes of the electrical device and the battery pack become larger, which does not facilitate carrying and use for a user. It should be noted that the “loading area” is understood as an area of an engaging region defined by a pair of guiding portions, that is, an area of an engaging region obtained by multiplying a size of the pair of guiding portions in the engaging direction A by a maximum distance between the pair of guiding portions in the width direction.

In the present embodiments, a ratio of energy of the first battery pack 2 to an area of an engaging region defined by the pair of first guiding portions 110a and 110b is defined as a first energy loading ratio, a ratio of energy of the second battery pack 3 to an area of an engaging region defined by the pair of second guiding portions 120a and 120b is defined as a second energy loading ratio, the first energy loading ratio is in a range of 2.05 to 5.58 Wh/cm², and/or the second energy loading ratio is in a range of 1.20 to 7.20 Wh/cm².

The first energy loading ratio and the second energy loading ratio are set in this way, so that when the loading requirement of the battery pack mounting portion 100 for the battery pack is satisfied, the energy of the battery pack can become as large as possible, thereby satisfying the usage requirement of increasing single-pack capacity.

Similarly, since the shapes and sizes of the first engaging portions 210a and 210b and the first guiding portions 110a and 110b are matched with each other, and the shapes and sizes of the second engaging portions 310a and 310b and the second guiding portions 120a and 120b are matched with each other, a ratio of energy of the first battery pack 2 to an area of an engaging region defined by the pair of first engaging portions 210a and 210b is defined as a first battery pack energy loading ratio, a ratio of energy of the second battery pack 3 to an area of an engaging region defined by the pair of second engaging portions 310a and 310b is defined as a second battery pack energy loading ratio, the first battery pack energy loading ratio is in a range of 2.05 to 5.58 Wh/cm², and/or the second battery pack energy loading ratio is in a range of 1.20 to 7.20 Wh/cm².

In some embodiments, the area of the engaging region defined by the first guiding portions 110a and 110b is 322.5 cm², the energy of the first battery pack 2 ranges from 600 to 1800 Wh, the area of the engaging region defined by the second guiding portions 120a and 120b is 100 cm², and the energy of the second battery pack 2 ranges from 120 to 720 Wh.

In some embodiments, the capacity of the first battery pack 2 is greater than the capacity of the second battery pack 3. In some embodiments, the capacity of the first battery pack 2 is 11 Ah, the capacity of the second battery pack 3 is 4 Ah, and rated voltages of the first battery pack 2 and the second battery pack 3 are both 60 V. The first battery pack 2 is configured to supply power to a power tool with a large volume and/or high power, such as a hand-push lawn mower or a blower, during use, the first battery pack 2 is directly mounted on the hand-push lawn mower, and the user does not need to directly burden the weight of the battery pack, or the first battery pack 2 is mounted on a back rack. The second battery pack 3 is configured to supply power to a handheld power tool, such as a grass trimmer or a branch trimmer, the second battery pack 3 is directly mounted on the handheld power tool, when using the handheld power tool, a worker does not need to supply power to the handheld power tool through a cable, making use more convenient.

In some embodiments, the weight of the first battery pack 2 is greater than the weight of the second battery pack 3. In some embodiments, a ratio of the weight of the first battery pack 2 to the weight of the second battery pack 3 ranges from 2 to 8. The weight of the first battery pack 2 ranges from 7.5 to 8.5 kg, and the weight of the second battery pack 3 ranges from 1.2 to 3.5 kg.

Since the weight of the first battery pack 2 is relatively large, in order to facilitate installation, as shown in FIG. 5, the first battery pack 2 further includes a handle 275 located at one end of the first housing 20, and the handle 275 is enclosed with the first housing 20 to form a grip area.

In some embodiments, the ratio of the length of the first engaging portion to the length of the first housing 20 in the engaging direction is 0.23-0.89. In some embodiments, the ratio of the maximum distance between the pair of first engaging portions to the width of the first housing 20 in the width direction perpendicular to the engaging direction is 0.56-0.69.

If the ratio of the length of the first engaging portion to the length of the first housing or the ratio of the maximum distance between the pair of first engaging portions to the width of the first housing is too large, the space of other structures provided on the first housing will be squeezed, if the ratio of the length of the first engaging portion to the length of the first housing or the ratio of the maximum distance between the pair of first engaging portions to the width of the first housing is too small, the engaging between the first battery pack and the electrical device will be unreliable, and if vibration is generated during transportation or operation, the first battery pack will easily fall off from the electrical device, thereby causing damage to the first battery pack.

In some embodiments, as shown in FIG. 15, the pair of first guiding portions 110a and 110b are arranged back to back, and the pair of second guiding portions 120a and 120b are arranged face to face. Based on this arrangement, the pair of first guiding portions 110a and 110b are configured as a pair of outer slide rails, and the pair of second guiding portions 120a and 120b are configured as a pair of inner slide rails, correspondingly, as shown in FIG. 5 and FIG. 8, the pair of first engaging portions 210a and 210b are configured as a pair of inner slide rails, and the pair of second engaging portions 310a and 310b are configured as a pair of outer slide rails.

Certainly, a person skilled in the art may also arranges the pair of first guiding portions face to face, that is, as a pair of inner slide rails, and the pair of second guiding portions back to back, that is, as a pair of outer slide rails, correspondingly, the pair of first engaging portions are configured as a pair of outer slide rails, and the pair of second engaging portions are configured as a pair of inner slide rails; or the pair of first guiding portions and the pair of second guiding portions are each configured as a pair of outer slide rails, correspondingly, the pair of first engaging portions and the pair of second engaging portions are each configured as a pair of inner slide rails; or the pair of first guiding portions and the pair of second guiding portions are each configured as a pair of inner slide rails, correspondingly, the pair of first engaging portions and the pair of second engaging portions are each configured as a pair of outer slide rails.

Further, the battery pack mounting portion 100 further includes a first support portion 130 and a second support portion 131, the pair of first guiding portions 110a and 110b include a pair of first extension portions 111a and 111b that extend in the engaging direction A, the pair of second guiding portions 120a and 120b include a pair of second extension portions 121a and 121b that extend in the engaging direction A, the first extension portion 111a protrudes from an outer side of the first support portion 130 in the width direction, the first extension portion 111b protrudes from an outer side of the second support portion 131 in the width direction, the second extension portion 121a protrudes from an inner side of the first support portion 130 in the width direction, and the second extension portion 121b protrudes from an inner side of the second support portion 131 in the width direction.

In other words, one first extension portion 111a of the pair of first extension portions and one second extension portion 121a of the pair of second extension portions share the first support portion 130, and the other first extension portion 111b of the pair of first extension portions and 121b of the pair of second extension portions share the second support portion 131. In such an arrangement, the layout of the battery pack mounting portion 100 can be compact, thereby reducing the space occupied by the battery pack mounting portion 100, and therefore reducing the volume of the electrical device 1.

It should be noted that the outer sides of the first support portion 130 and the second support portion 131 refers to sides of the first support portion 130 and the second support portion 131 away from the center line of the pair of first guiding portions 110a and 110b and the center line of the pair of second guiding portions 120a and 120b, and the inner sides of the first support portion 130 and the second support portion 131 refers to sides of the first support portion 130 and the second support portion 131 close to the center line of the pair of first guiding portions and the center line of the pair of second guiding portions. In some embodiments, as shown in FIG. 1, the outer side refers to a left side, and the inner side refers to a right side.

Further, the first guiding portion 110a further includes an outer sidewall 132 of the first support portion 130, and the first guiding portion 110b further includes an outer sidewall 133 of the second support portion 131. Correspondingly, the first engaging portion includes an inner sidewall configured to engage with the first extension portion, and a first contact portion engaging with an outer sidewall of the first guiding portion, as shown in FIG. 5, using the first engaging portion 210a as an example, the first engaging portion 210a includes an inner sidewall (not shown) engaging with the first extension portion 111a, and a first contact portion 211a engaging with an outer sidewall 132. Therefore, when the first battery pack 2 slidably engages with the electrical device 1 in the engaging direction A, the first extension portion 111a, the outer sidewall 132, the second extension portion 111b, and the outer sidewall 133 jointly constitute guidance and restriction for the first battery pack 2.

Similarly, the second guiding portion 120a further includes an inner sidewall 134 of the first support portion 130, and the second guiding portion 120b further includes an inner sidewall 135 of the second support portion 131. Correspondingly, the second engaging portion includes an outer sidewall configured to engage with the second extension portion, and a second contact portion engaging with an inner sidewall of the second guiding portion, as shown in FIG. 8, using the second engaging portion 310a as an example, the second engaging portion 310a includes an outer sidewall 312 engaging with the second extension portion 121a, and a second contact portion 311a engaging with an inner sidewall 134. Therefore, when the second battery pack 3 slidably engages with the electrical device 1 in the engaging direction A, the second extension portion 121a, the inner sidewall 134, the second extension portion 121b, and the inner sidewall 135 jointly constitute guidance and restriction for the second battery pack 3.

In some embodiments, as shown in FIG. 15, the battery pack mounting portion 100 further includes a plurality of device terminals 140 located between the pair of second guiding portions 120a and 120b, and the device terminals 140 are evenly distributed in the width direction, correspondingly, the first battery pack 2 includes a plurality of first terminals (not shown) located between the first engaging portions 210a and 210b, and the second battery pack 3 includes a plurality of second terminals (not shown) located between the second engaging portions 310a and 310b. When the first battery pack 2 engages with the electrical device 1, a device terminal 140 is configured to be electrically connected to a corresponding first terminal, to implement power transmission between the first battery pack 2 and the electrical device 1; when the second battery pack 3 engages with the electrical device 1, a device terminal 140 is configured to be electrically connected to a corresponding second terminal, to implement power transmission between the second battery pack 3 and the electrical device 1.

It should be noted that the device terminal 140, the first terminal, and the second terminal could be arranged in any form readily conceivable to a person skilled in the art. Details are not described herein again in the present embodiments.

Both the first battery pack 2 and the second battery pack 3 can engage with the device terminal 140, and there is no need to arrange two types of device terminals, resulting in a simple and compact structure, to facilitate miniaturization of the electrical device.

Specifically, the device terminals 140 includes a positive device terminal and a negative device terminal, correspondingly, the first terminals include a first positive terminal and a first negative terminal, and the second terminals include a second positive terminal and a second negative terminal. When the first battery pack 2 engages with the electrical device 1, the positive device terminal is pluggably connected to the first positive terminal, and the negative device terminal is pluggably connected to the first negative terminal, to implement power transmission between the first battery pack 2 and the electrical device 1. When the second battery pack 3 engages with the electrical device 1, the positive device terminal is pluggably connected to the second positive terminal, and the negative device terminal is pluggably connected to the second negative terminal, to implement power transmission between the second battery pack 3 and the electrical device 1.

Further, the device terminals 140 further include at least one signal device terminal 143, the first terminals further include at least one first signal terminal, and the second terminals further include at least one second signal terminal. When the first battery pack 2 engages with the electrical device 1, the signal device terminal is pluggably connected to the first signal terminal, to implement signal transfer between the first battery pack 2 and the electrical device 1. When the second battery pack 3 engages with the electrical device 1, the signal device terminal is pluggably connected to the second signal terminal, to implement signal transfer between the second battery pack 3 and the electrical device 1.

It should be noted that, in some embodiments, the specific structure of the device terminal 140 is basically the same as that of the device terminal 514a described above.

In some embodiments, a terminal socket 145 is arranged on the device housing 10, and the device terminal 140 is at least partially mounted on the terminal socket 145. Correspondingly, as shown in FIG. 4, the first housing 20 is provided with a plurality of first terminal slots 245 located between the pair of first engaging portions 210a and 210b, and each first terminal is at least partially received in one first terminal slot 245. As shown in FIG. 6, the second housing 30 is provided with a plurality of second terminal slots 345 located between the pair of second engaging portions 310a and 310b, and each second terminal is at least partially received in one second terminal slot 345.

In some embodiments, the battery pack mounting portion further includes a locking member 150 located between the pair of second guiding portions 120a and 120b, correspondingly, as shown in FIG. 5, the first mounting portion 200 includes a first locking portion 250 located between the pair of first engaging portions 210a and 210b, as shown in FIG. 8, the second mounting portion 300 includes a second locking portion 350 located between the pair of second engaging portions 310a and 310b. When the first battery pack 2 engages with the electrical device 1, the locking member 150 is configured to engage with the first locking portion 250, to lock the first battery pack 2 to the electrical device 1; when the second battery pack 3 engages with the electrical device 1, the locking member 150 is configured to engage with the second locking portion 350, to lock the second battery pack 3 to the electrical device 1.

When engaging with the electrical device 1, the first battery pack 2 and the second battery pack 3 can share the locking member 150, resulting in a simple and compact structure, to facilitate miniaturization of the electrical device.

In some embodiments, the locking member 150 is configured as a snap, and the first locking portion 250 and the second locking portion 350 are configured as slots that engage with the snap.

Further, the electrical device 1 further includes a triggering member 151. The triggering member 151 can drive the locking member 150 to move from a locked position to an unlocked position, when the locking member 150 is in the locked position, the locking member 150 engages with the first locking portion 250 or the second locking portion 350, to lock the electrical device 1 to the first battery pack 2 or the second battery pack 3; when the locking member 150 is in the unlocked position, the locking member 150 disengages from engaging with the first locking portion 250 or the second locking portion 350, to unlock the electrical device 1 from the first battery pack 2 or the second battery pack 3. In some embodiments, the triggering member 151 is configured as a button.

It should be noted that the locking member 150, the first locking portion 250, and the second locking portion 350 may be configured in other forms. For example, the locking member 150 is configured as a slot, and the first locking portion 250 and the second locking portion 350 are configured as snaps that engage with the slot. This is not limited in the present embodiments.

As mentioned above, in the conventional techniques, the first battery pack usually adopts a cable type. The first battery pack is mechanically connected to the backpack device, but electrically connected to the electrical device. The first battery pack cannot be directly mounted on the electrical device, which will cause the first battery pack cannot use the fan in the electrical device for ventilation and heat dissipation. Therefore, the prior first battery pack either provides an air vent for natural ventilation cooling, but this will lead to poor cooling effect; Either a fan is provided inside the first battery pack, but this will increase the volume and weight of the battery pack, which is not conducive to the user's carrying and use.

In order to overcome the above problems, in some embodiments, as shown in FIG. 5, the first battery pack 2 further includes a first air vent 260 disposed on the first housing 20, the first air vent 260 configured to be at least partially aligned with a device air vent of the electrical device 1 when the first battery pack 2 is engaged with the electrical device 1 to allow airflow to flow between the first air vent 260 and the device air vent. In this way, the first battery pack can use the fan in the electrical device to cool the first battery cell, and the heat dissipation effect is good without increasing the volume and weight of the battery pack.

Correspondingly, as shown in FIG. 16, the electrical device 1 further includes a device air vent 160, When the first battery pack 2 engages with the electrical device 1, air flow can flow into and/or out from the device air vent 160, to cool the first battery pack 2 and/or the electrical device 1; when the second battery pack 3 engages with the electrical device 1, air flow can flow into and/or out from the device air vent 160, to cool the second battery pack 3 and/or the electrical device 1.

In some embodiments, as shown in FIG. 5, the first vent 260 is located between the pair of first engaging portions 210a, 210b in the width direction. As shown in FIG. 16, the device air vent 160 is located between the pair of second guiding portions 120a and 120b in the width direction. As an example, the first air vent 260 is located between the first locking portion 250 and the first terminal in the engaging direction A. In the engaging direction A, the device air vent 160 is located between the locking member 150 and the device terminal 140.

As shown in FIG. 8, the second battery pack 3 further includes a second air vent 360 located between the pair of second engaging portions 310a and 310b, when the second battery pack 3 engages with the electrical device 1, the second air vent 360 is at least partially aligned with the device air vent 160, to implement air flow conduction between the second battery pack 3 and the electrical device 1.

Further, the electrical device 1 further includes a fan 101 arranged in the device housing 10. the first air vent 260 configured to be at least partially aligned with a device air vent 160 when the first battery pack 2 is engaged with the electrical device 1, the fan is configured as, drive airflow flows between the first air vent 260 and the device air vent 160.

In some embodiments, the fan is configured as a suction fan, the device air vent 160 is configured as an air inlet of the electrical device 1, the first air vent 260 is configured as an air outlet of the first battery pack 2. As shown in FIG. 19, the first battery pack 2 further includes an air inlet 280, when the first battery pack 2 is engaged with the electrical device 1, the fan 101 is configured as, drive airflow flows into the first housing 20 from the air inlet 280, flows out from the first air vent 260 after cooling the first battery cell 201. As an example, the air inlet 280 is located at least partially at a side or bottom of the first housing 20.

Further, the electrical device 1 further includes a device air outlet (not shown), cooling air can flow out of the first battery pack 2 from the first air vent 260, and then enter the device housing 10 through the device air vent 160, to cool heat-generating electronic devices in the electrical device 1, finally flows out of the electric device 1 from the device air outlet.

In some embodiments, the fan 101 is configured as a blowing fan, the device air vent 160 is configured as an air outlet of the electrical device 1, the first air vent 260 is configured as an air inlet of the first battery pack 2, the first battery pack 2 further includes an air outlet (not shown). When the electrical device 1 engages with the first battery pack 2, the fan 101 is configured to drive the airflow to flow out from the device air vent 160, then enter the first battery pack 2 through the first air vent 260, cool the first battery cell 201 and then flow out of the first battery pack 2 from the air outlet.

Further, the electrical device 1 further includes a device air inlet (not shown), cooling air can flow in from the device air inlet, after cooling heat-generating electronic devices in the electrical device 1, then flow out from the device air vent 160, and finally enter the first battery pack 2 from the first air vent 260, to cool the first battery pack 2.

In some embodiments, the electrical device 1 does not include a fan, and is cooled by using natural wind. The cooling air can flow in from the device air vent 160 and flow out from the device air vent 160, to cool heat-generating electronic devices in the electrical device 1.

When engaging with the electrical device 1, the first battery pack 2 and the second battery pack 3 can share the device air vent 160, resulting in a simple and compact structure, to facilitate miniaturization of the electrical device.

As shown in FIG. 8 and FIG. 20, the second battery pack 3 further includes a second air vent 360 located on the device housing 10, and when the second battery pack 3 is engaged with the electrical device 1, the second air vent 360 is at least partially aligned with the device air vent 160 to achieve airflow conduction between the second battery pack 3 and the electrical device 1. As an example, in the width direction, the second air vent 360 is located between the pair of second engaging portions 310a and 310b. As an example, in the engaging direction A, the second air vent 360 is located between the second locking portion 350 and the second terminal.

Regarding how to cool the second battery cell by using the fan in the electrical device when the second battery pack is mounted on the electrical device, the contents of the first battery pack being mounted on the electrical device may be referred to and will not be repeatedly described here.

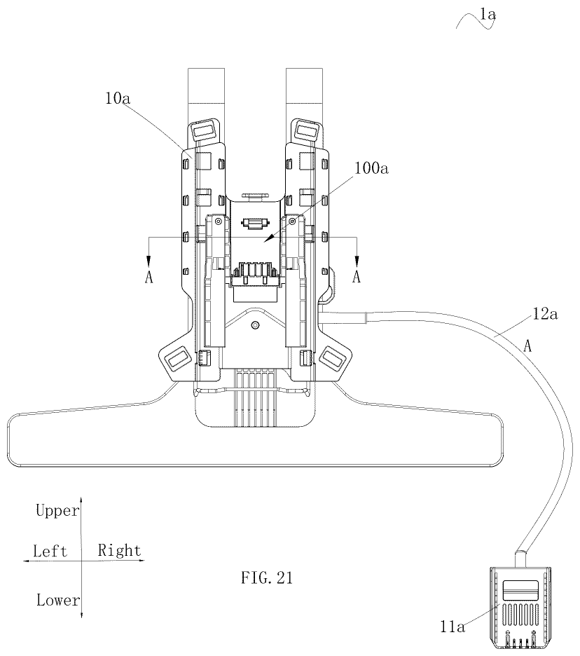

In some embodiments, as shown in FIG. 21, an electrical device 1a may also configured as a back-carrying apparatus for a user to carry on the back. The electrical device 1a includes a battery pack mounting portion 100a arranged on a device housing 10a, the battery pack mounting portion 100a is configured to engage with a first battery pack 2 or a second battery pack 3. The electrical device 1a further includes an adapter 11a, the adapter 11a is configured to engage with a power tool, the adapter 11a is electrically connected to the battery pack mounting portion 100a through a cable 12a. When the first battery pack 2 or the second battery pack 3 engages with the electrical device 1a, and the adapter 11a engages with the power tool, the first battery pack 2 or the second battery pack 3 can transfer power to the power tool.

The structure of the battery pack mounting portion 100a is the same as that of the foregoing battery pack mounting portion 100. Details are not described herein again in the present embodiments.

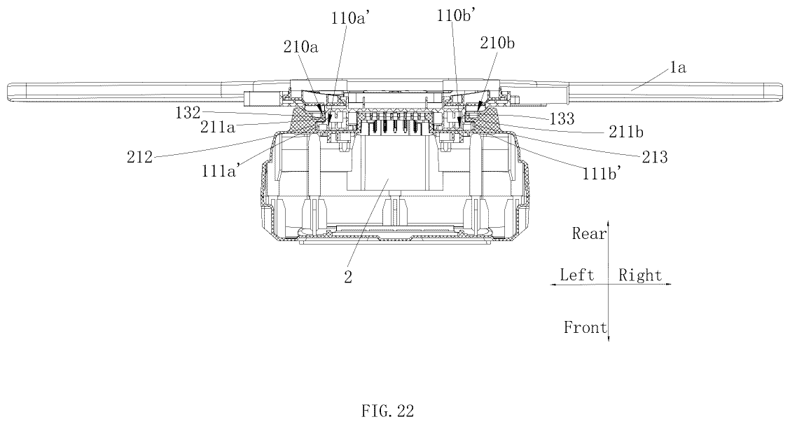

As shown in FIG. 22, a first battery pack 2 engages with an electrical device 1a, in a width direction, a maximum distance between a pair of first guiding portions 110a′ and 110b′ is substantially the same as a maximum distance between a pair of first engaging portions 210a and 210b. The first guiding portion 110a′ engages with the first engaging portion 210a, the first guiding portion 110b′ engages with the first engaging portion 210b, specifically, a first extension portion 111a′ engages with an inner sidewall 212 of the first battery pack 2, a first extension portion 111b′ engages with an inner sidewall 213 of the first battery pack, an outer sidewall 132 of the first guiding portion 110a′ engages with a first contact portion 211a, and an outer sidewall 133 of the first guiding portion 110b′ engages with a first contact portion 211b, so the first battery pack 2 can be slidably mounted on the electrical device 1a in an engaging direction A.

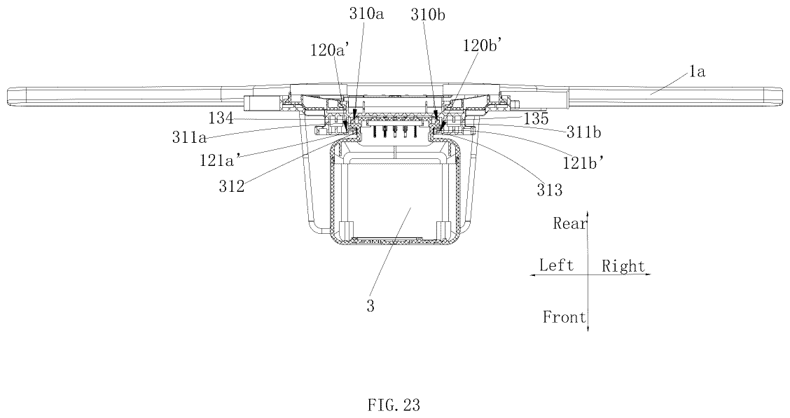

As shown in FIG. 23, a second battery pack 3 engages with an electrical device 1a, in a width direction, a maximum distance between a pair of second guiding portions 120a′ and 120b′ is substantially the same as a maximum distance between a pair of second engaging portions 310a and 310b. The second guiding portion 120a′ engages with the second engaging portion 310a, the second guiding portion 120b′ engages with the second engaging portion 310b, specifically, a second extension portion 121a′ engages with an outer sidewall 312 of the second battery pack 3, a second extension portion 121b′ engages with an outer sidewall 313 of the second battery pack 3, an inner sidewall 134 of the second guiding portion 120a′ engages with a second contact portion 311a of the second battery pack, and an inner sidewall 135 of the second guiding portion 120b′ engages with a second contact portion 311b, so the second battery pack 3 can be slidably mounted on the electrical device 1a in an engaging direction A.

According to the back-carrying apparatus provided by the present embodiments, the first guiding portion and the second guiding portion are arranged at the battery pack mounting portion, so that not only two types of battery packs can be mounted, but also space of the back-carrying apparatus can be saved.

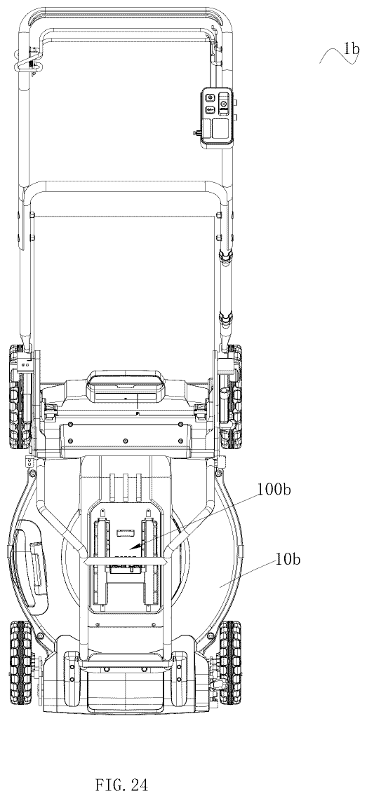

In some embodiments, the electrical device is configured as a power tool or a household appliance. The power tool is configured as a lawn mower, a grass trimmer, a blower, or the like in some embodiments. The household appliance is configured as an electric fan, a vacuum cleaner, or the like in some embodiments. As shown in FIG. 24, an electrical device 1b could be configured as a lawn mower. The electrical device 1b includes a battery pack mounting portion 100b arranged on a device housing 10b. The battery pack mounting portion 100b is configured to engage with a first battery pack 2 or a second battery pack 3. When the first battery pack 2 or the second battery pack 3 engages with the electrical device 1b, the first battery pack 2 or the second battery pack 3 can provide power to the electrical device 1b.

Similarly, the structure of the battery pack mounting portion 100b is the same as that of the foregoing battery pack mounting portion 100. Details are not described herein again in the present embodiments.

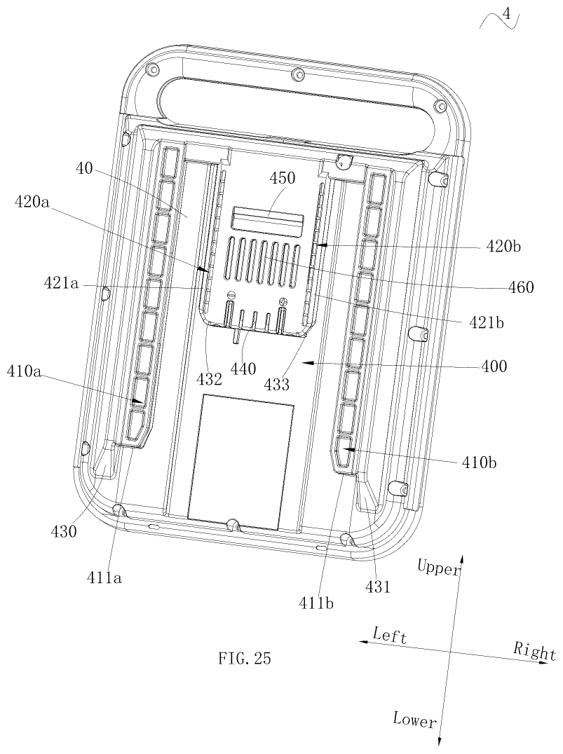

As shown in FIG. 25, some embodiments of the present embodiments further provide a battery pack 4. The battery pack 4 includes a battery pack housing 40, an electrical device mounting portion 400 is arranged on the battery pack housing 40, and the electrical device mounting portion 400 is configured to detachably engage with a first electrical device or a second electrical device.

The electrical device mounting portion 400 includes a pair of first leading portions 410a and 410b and a pair of second leading portions 420a and 420b, the first leading portions 410a and 410b are configured to guide the battery pack 4 to engage with the first electrical device (not shown) in an engaging direction B, the second leading portions 420a and 420b are configured to guide the battery pack 4 to engage with the second electrical device (not shown) in the engaging direction B, the first leading portions 410a and 410b and the second leading portions 420a and 420b are independent of each other, and in a width direction perpendicular to the engaging direction B, the pair of first leading portions 410a and 410b are located on two sides of the pair of second leading portions 420a and 420b.

The battery pack 4 can adapt to electrical devices with two different interface sizes, to facilitate universality of the battery pack 4, and projection regions of the two types of guiding portions on a plane perpendicular to the width direction at least partially overlap, to reduce the size of the electrical device mounting portion 400 and facilitate miniaturization of the battery pack 4.

The structure of the electrical device mounting portion 400 is substantially the same as that of the foregoing battery pack mounting portion 100. For ease of description, the same structure of the battery pack 3 as that of the battery pack 1 is not repeated. Different structures are discussed in detail below.

In some embodiments, as shown in FIG. 11, a pair of first leading portions 410a and 410b are arranged face to face, and a pair of second leading portions 420a and 420b are arranged back to back. Based on the foregoing arrangement, the pair of first leading portions 410a and 410b are configured as inner slide rails, and the pair of second leading portions 420a and 420b are configured as outer slide rails, correspondingly, a pair of outer slide rails are arranged on the first electrical device, and a pair of inner slide rails are arranged on the second electrical device. Certainly, referring to the description of the foregoing battery pack mounting portion 100, the arrangement of the first guiding portion and the second guiding portion could also be other forms. Details are not described herein again.

Further, the electrical device mounting portion 400 further includes a first connection portion 430, a second connection portion 431, a third connection portion 432, and a fourth connection portion 433. The pair of first leading portions 410a and 410b respectively include a pair of first projection portions 411a and 411b extending in an engaging direction A, the pair of second leading portions 420a and 420b respectively include a pair of second projection portions 421a and 421b extending in the engaging direction A, the first projection portion 411a protrudes from an inner side of the first connection portion 430 in the width direction, the first projection portion 411b protrudes from an inner side of the second connection portion 431 in the width direction, the second projection portion 421a protrudes from an outer side of the third connection portion 432 in the width direction, the second projection portion 421b protrudes from an outer side of the fourth connection portion 433 in the width direction.

Likewise, similar to the foregoing battery pack mounting portion 100, the electrical device mounting portion 400 also includes a plurality of battery pack terminals 440 that are located between the pair of first leading portions 410a and 410b, a locking portion 450, and a battery pack air vent 460. For specific arrangements and structural forms of these components, reference is made to the foregoing part. Details are not described herein again. In such an arrangement, the first electrical device and the second electrical device can share these components, so that the structure is simple and compact, thereby miniaturizing the battery pack.

The technical features in the foregoing embodiments may be randomly combined. For concise description, not all possible combinations of the technical features in the embodiment are described. However, provided that combinations of the technical features do not conflict with each other, the combinations of the technical features are considered as falling within the scope recorded in this specification.

The foregoing embodiments only describe several implementations of the present embodiments, and their description is specific and detailed, but cannot therefore be understood as a limitation to the patent scope of the present embodiments. It should be noted that for a person of ordinary skill in the art, several transformations and improvements can be made without departing from the idea of the present embodiments. These transformations and improvements belong to the protection scope of the present embodiments. Therefore, the protection scope of the patent of the present embodiments shall be subject to the appended claims.

What is claimed is:

1. An electrical system comprising:
a first type power tool configured as at least one of a backpack power tool and a wheeled power tool;
a second type power tool configured as a handheld power tool different from the first type power tool;
a first battery pack comprising a first mounting portion; and
a second battery pack comprising a second mounting portion, the second mounting portion being different from the first mounting portion,
wherein:
the first type power tool comprises a battery pack mounting portion configured to detachably engage with the first mounting portion;
the second type power tool comprises a battery pack mounting part configured to detachably engage with the second mounting portion and to be non-engaged with the first mounting portion;
a weight of the first battery pack is greater than or equal to 3.6 kg;
the weight of the first battery pack is greater than a weight of the second battery pack; and
a capacity of the first battery pack is greater than a capacity of the second battery pack.

2. The electrical system according to claim 1, wherein:
the battery pack mounting portion comprises a first type battery pack mechanical interface and a first type battery pack electrical interface;
the battery pack mounting part comprises a second type battery pack mechanical interface and a second type battery pack electrical interface;
the first mounting portion comprises a first mechanical interface and a first electrical interface;
the second mounting portion comprises a second mechanical interface and a second electrical interface;
the first electrical interface is electrically connected to a first type battery pack electrical interface when the first mechanical interface is engaged with the first type battery pack mechanical interface; and/or
the second electrical interface is electrically connected to a second type battery pack electrical interface when the second mechanical interface is engaged with the second type battery pack mechanical interface.

3. The electrical system according to claim 1, wherein:
the battery pack mounting portion comprises a first type battery pack mechanical interface;
the battery pack mounting part comprises a second type battery pack mechanical interface;
the first mounting portion comprises a first mechanical interface;
the second mounting portion comprises a second mechanical interface;
an engaging mode between the first type battery pack mechanical interface and the first mechanical interface is defined as a first engaging mode; and
an engaging mode between the second type battery pack mechanical interface and the second mechanical interface is defined as a second engaging mode, the first engaging mode being same as the second engaging mode.

4. The electrical system according to claim 1, wherein:
the first mechanical interface comprises a pair of first engaging portions, the first engaging portions being configured to guide the first battery pack to engage with the battery pack mounting portion in an extending direction of the first engaging portions; and/or
the second mechanical interface comprises a pair of second engaging portions, the second engaging portions are configured to guide the second battery pack to engage with the battery pack mounting part in an extending direction of the second engaging portions.

5. The electrical system according to claim 4, wherein:
a ratio of a length of a respective first engaging portion to a length of a respective second engaging portion ranges from 1.5 to 2; and/or
a ratio of a maximum distance between the pair of first engaging portions to a maximum distance between the pair of second engaging portions ranges from 1.5 to 2.5.

6. The electrical system according to claim 4, wherein:
a ratio of energy of the first battery pack to an area of an engaging region defined by the pair of first engaging portions is defined as a first battery pack energy loading ratio;
a ratio of energy of the second battery pack to an area of an engaging region defined by the pair of second engaging portions is defined as a second battery pack energy loading ratio;
the first battery pack energy loading ratio is in a range of 2.05 to 5.58 Wh/cm²; and/or
the second battery pack energy loading ratio is in a range of 1.20 to 7.20 Wh/cm².

7. The electrical system according to claim 1, wherein the ratio of the weight of the first battery pack to the weight of the second type power tool is 0.5-4.

8. The electrical system according to claim 1, wherein the battery pack mounting portion is configured to detachably engage with the second mounting portion to cause the second battery pack to power the first type power tool.

9. The electrical system according to claim 1, wherein a ratio of the weight of the first battery pack to the weight of the second battery pack ranges from 2 to 8.

10. The electrical system according to claim 1, wherein a ratio of an energy of the first battery pack to an energy of the second battery pack is greater than or equal to 2.

11. The electrical system according to claim 1, wherein:
the energy of the first battery pack ranges from 600 to 1800 Wh; and/or
the energy of the second battery pack ranges from 120 to 720 Wh.

12. The electrical system according to claim 1, wherein the electrical system further includes a charger, the charger including a battery pack mounting portion configured to detachably engage with the first mounting portion or the second mounting portion to charge the first battery pack or the second battery pack.

13. A first battery pack comprising,
a first housing;
at least one first battery cell accommodated in the first housing; and
a first mounting portion configured to detachably engage with an electrical device, the first mounting portion comprising a first mechanical interface and a first electrical interface,
wherein:
a weight of the first battery pack is greater than or equal to 3.6 kg; and
the first electrical interface is electrically connected to corresponding electrical interface of an electrical device when the first mechanical interface is engaged with corresponding mechanical interface of the electrical device.

14. The first battery pack according to claim 13, wherein:
the first electrical interface comprises a plurality of first terminals; and
the plurality of first terminals are electrically connected to corresponding terminals of the electrical device when the first mounting portion is engaged with the electrical device.

15. The first battery pack according to claim 13, wherein:
the first mechanical interface comprises a pair of first engaging portions;
the pair of first engaging portions are arranged on the first housing; and
the pair of first engaging portions are configured to guide the first battery pack to engage with the electrical device in an engaging direction, the engaging direction being configured as an extending direction of the first engaging portions.

16. The first battery pack according to claim 15, wherein:
in the engaging direction, a ratio of a length of a respective first engaging portion to a length of the first housing ranges from 0.23 to 0.89; and/or
in a width direction perpendicular to the engaging direction, a ratio of a maximum distance between the pair of first engaging portions to a width of the first housing ranges from 0.56 to 0.69.

17. The first battery pack according to claim 13, wherein:
an energy of the first battery pack ranges from 600 to 1800 Wh; and/or
a weight of the first battery pack ranges from 4 to 12 Kg.

18. The first battery pack according to claim 13, wherein:
a ratio of energy of the first battery pack to an area of an engaging region defined by the pair of first engaging portions is defined as a first battery pack energy loading ratio; and
the first battery pack energy loading ratio is in a range of 2.05 to 5.58 Wh/cm².

19. A first battery pack comprising,
a first housing;
at least one first battery cell accommodated in the first housing, a weight of the at least one first battery pack is greater than or equal to 3.6 kg; and
a first air vent located on the first housing and configured to be at least partially aligned with a device air vent of an electrical device when the first battery pack is engaged with the electrical device to allow airflow to flow between the first air vent and the device air vent.

20. The first battery pack according to claim 19, wherein:
the first battery pack further comprises a pair of first engaging portions configured to guide the first battery pack to engage with the electrical device in an engaging direction;
in a width direction perpendicular to the engaging direction, the first air vent located between the pair of first engaging portions; and
the engaging direction is configured as an extending direction of the first engaging portions.
